(19) United States
(12) Patent Application Publication
(10) Pub. No.: US 2024/0120198 A1
(43) Pub. Date: Apr. 11, 2024

(54) CONVEYANCE APPARATUS, CONVEYANCE METHOD, AND METHOD FOR MANUFACTURING SEMICONDUCTOR DEVICE

(71) Applicant: JSW Aktina System Co., Ltd., Yokohama-shi, Kanagawa (JP)

(72) Inventors: Yoshihiro YAMAGUCHI, Yokohama-shi, Kanagawa (JP); Takahiro FUJI, Yokohama-shi, Kanagawa (JP); Hiroaki IMAMURA, Yokohama-shi, Kanagawa (JP)

(73) Assignee: JSW Aktina System Co., Ltd., Yokohama-shi, Kanagawa (JP)

(21) Appl. No.: 18/271,613

(22) PCT Filed: Jan. 27, 2022
(86) PCT No.: PCT/JP2022/003187

§ 371 Date: Jul. 10, 2023

(30) Foreign Application Priority Data
Jan. 29, 2021 (JP) 2021-012922

(51) Int. Cl. H01L 21/02; H01L 21/67; H01L 21/677; H01L 21/683

(52) U.S. Cl. CPC H01L 21/02675; H01L 21/67115; H01L 21/67715; H01L 21/67784; H01L 21/6838

(57) ABSTRACT

A conveyance apparatus configured to convey a substrate (100) in order to irradiate the substrate (100) with laser light for forming a line-shaped irradiation area (15a) according to an embodiment includes a levitation unit (10) configured to levitate the substrate (100) over its top surface, a holding mechanism (12) configured to hold the substrate (100), and a moving mechanism (13) configured to move the holding mechanism (12) in a direction inclined from a direction perpendicular to a longitudinal direction of the line-shaped laser light in a plan view so as to change an irradiation place of the laser light in the substrate (100).

### TECHNICAL FIELD

The present disclosure relates to a conveyance apparatus, a conveyance method, and a method for manufacturing a semiconductor device.

### BACKGROUND ART

Patent Literature 1 discloses a laser annealing apparatus for forming a polycrystalline silicon thin film. In Patent Literature 1, a projection lens focuses laser light over a substrate so that a linear irradiation area is formed therein. As a result, an amorphous silicon film is crystallized and becomes a polysilicon film.

In Patent Literature 1, a conveyance unit conveys the substrate in a state where the substrate is levitated, i.e., floated, by a levitation unit. Further, the substrate is carried into and out of the levitation unit at the same place therein. The conveyance unit conveys the substrate along each of the sides of the levitation unit. Further, the substrate moves round twice (i.e., is conveyed so as to go round along the four sides of the levitation unit twice) over the levitation unit, so that substantially the entire surface of the substrate is irradiated with laser light.

### CITATION LIST

### Patent Literature

Patent Literature 1: Japanese Unexamined Patent Application Publication No. 2018-64048

### SUMMARY OF INVENTION

In such a conveyance apparatus for a laser irradiation apparatus, it is desired to appropriately convey a substrate so that a laser irradiation process is performed at a high speed and in a stable manner.

Other problems to be solved and novel features will become apparent from descriptions in this specification and accompanying drawings.

According to an embodiment, a conveyance apparatus configured to convey a substrate in order to irradiate the substrate with line-shaped laser light includes: a substrate levitation unit configured to levitate the substrate over its top surface; a holding mechanism configured to hold the substrate; and a moving mechanism configured to move the holding mechanism in a direction inclined from a direction perpendicular to the line-shaped laser light in a plan view so as to change an irradiation place of the laser light in the substrate.

According to another embodiment, a conveyance apparatus configured to convey a substrate in order to irradiate the substrate with line-shaped laser light includes: a first substrate levitation unit disposed below the substrate, the first substrate levitation unit being configured to levitate the substrate, and being disposed at a part of the substrate extending from a central part of the substrate to one end thereof in a plan view; a second substrate levitation unit disposed below the substrate, the second substrate levitation unit being configured to levitate the substrate, and being disposed at another part of the substrate extending from the central part of the substrate to the other end thereof in the plan view; a holding mechanism disposed below the central part of the substrate, the holding mechanism being configured to hold the substrate by absorbing the substrate; and a moving mechanism configured to move the holding mechanism along a gap between the first and second substrate levitation units in order to move the substrate with respect to an irradiation place of the laser light.

According to another embodiment, a conveyance method for conveying a substrate in order to irradiate the substrate with line-shaped laser light includes the steps of: (a) levitating, by a levitation unit disposed below the substrate, the substrate over its top surface; (b) holding, by a holding mechanism, the substrate; and (c) moving the holding mechanism in a direction inclined from a direction perpendicular to a longitudinal direction of the line-shaped laser light in a plan view so as to change an irradiation place of the laser light in the substrate.

According to another embodiment, a conveyance method for conveying a substrate in order to irradiate the substrate with line-shaped laser light includes the steps of: (A) levitating a part of the substrate extending from a central part of the substrate to one end thereof in a plan view by using a first substrate levitation unit disposed below the substrate, and levitating another part of the substrate extending from the central part of the substrate to the other end thereof in the plan view by using a second substrate levitation unit disposed below the substrate; (B) holding the substrate by absorbing the substrate by using a holding mechanism disposed below the central part of the substrate; and (C) moving the holding mechanism along a gap between the first and second substrate levitation units in order to move the substrate with respect to an irradiation place of the laser light.

According to another embodiment, a method for manufacturing a semiconductor device includes the steps of: (s1) forming an amorphous film over a substrate; and (s2) annealing the amorphous film by irradiating the substrate with line-shaped laser light so as to crystallize the amorphous film and thereby form a crystallized film, in which the annealing step (s2) includes the steps of: (sa) levitating, by a levitation unit, the substrate over its top surface; (sb) holding, by a holding mechanism, the substrate; and (sc) moving the holding mechanism in a direction inclined from a direction perpendicular to a longitudinal direction of the line-shaped laser light in a plan view so as to change an irradiation place of the laser light in the substrate.

According to another embodiment, a method for manufacturing a semiconductor device includes the steps of: (S1) forming an amorphous film over a substrate; and (S2) annealing the amorphous film by irradiating the substrate with line-shaped laser light so as to crystallize the amorphous film and thereby form a crystallized film, in which the annealing step (S2) includes the steps of: (SA) levitating a part of the substrate extending from a central part of the substrate to one end thereof in a plan view by using a first substrate levitation unit disposed below the substrate, and levitating another part of the substrate extending from the central part of the substrate to the other end thereof in the plan view by using a second substrate levitation unit disposed below the substrate; (SB) holding the substrate by absorbing the substrate by using a holding mechanism disposed below the central part of the substrate; and (SC) moving the holding mechanism along a gap between the first and second substrate levitation units in order to move the substrate with respect to an irradiation place of the laser light.

According to the above-described embodiments, it is possible to perform conveyance of a substrate suitable for a laser irradiation process.

### BRIEF DESCRIPTION OF DRAWINGS

FIG. 1 is a plan view schematically showing a laser irradiation apparatus according to a first embodiment;

FIG. 2 is a side cross-sectional view schematically showing the laser irradiation apparatus according to the first embodiment;

FIG. 3 is a diagram for explaining a distribution of intensity of pulsed laser light;

FIG. 4 is a plan view showing an irradiation pitch of pulsed laser light and a manufacturing pitch of TFTs;

FIG. 5 is a plan view showing an irradiation pitch of pulsed laser light and a manufacturing pitch of a TFT;

FIG. 6 is a plan view showing a configuration of a conveyance apparatus according to a second embodiment;

FIG. 7 is a plan view of the conveyance apparatus for explaining a convey process performed therein;

FIG. 8 is a plan view of the conveyance apparatus for explaining the convey process performed therein;

FIG. 9 is a plan view of the conveyance apparatus for explaining the convey process performed therein;

FIG. 10 is a plan view of the conveyance apparatus for explaining the convey process performed therein;

FIG. 11 is a plan view of the conveyance apparatus for explaining the convey process performed therein;

FIG. 12 is a plan view of the conveyance apparatus for explaining the convey process performed therein;

FIG. 13 is a plan view of the conveyance apparatus for explaining the convey process performed therein;

FIG. 14 is a plan view of the conveyance apparatus for explaining the convey process performed therein;

FIG. 15 is a perspective view schematically showing a part of a holding mechanism;

FIG. 16 is a schematic diagram showing a configuration of the holding mechanism;

FIG. 17 is a schematic diagram showing an exhaust system of the holding mechanism;

FIG. 18 is a schematic diagram for explaining control of valves of the holding mechanism;

FIG. 19 is a side view schematically showing a configuration of a conveyance apparatus;

FIG. 20 is a plan view schematically showing a laser irradiation apparatus according to a third embodiment;

FIG. 21 is a schematic diagram for explaining an absorption destruction due to a moment of inertia;

FIG. 22 is a schematic diagram for explaining absorption peeling electrification;

FIG. 23 is a plan view for explaining an irradiation process according to an Example 1;

FIG. 24 is a plan view for explaining an irradiation process according to an Example 2;

FIG. 25 is a plan view for explaining an irradiation process according to an Example 3;

FIG. 26 is a simplified cross-sectional view of an organic EL display;

FIG. 27 is a cross-sectional view showing a step in a method for manufacturing a semiconductor device according to an embodiment;

FIG. 28 is a cross-sectional view showing a step in the method for manufacturing a semiconductor device according to the embodiment;

FIG. 29 is a plan view schematically showing a configuration of a first modified example;

FIG. 30 is a plan view schematically showing a configuration of a second modified example;

FIG. 31 shows plan views for explaining configurations of an Irradiation Example 1;

FIG. 32 shows plan views for explaining configurations of an Irradiation Example 2;

FIG. 33 shows plan views for explaining configurations of the Irradiation Example 2;

FIG. 34 shows plan views for explaining configurations of an Irradiation Example 3;

FIG. 35 is a plan view for explaining a configuration of an Irradiation Example 4;

FIG. 36 is a plan view for explaining a configuration of the Irradiation Example 4;

FIG. 37 is a plan view for explaining a configuration of an Irradiation Example 5;

FIG. 38 is a plan view for explaining a configuration of the Irradiation Example 5;

FIG. 39 is a plan view schematically showing a configuration in which two substrates are simultaneously conveyed;

FIG. 40 is a plan view schematically showing a configuration in which two substrates are simultaneously conveyed;

FIG. 41 is a plan view schematically showing a configuration in which two substrates are simultaneously conveyed; and

FIG. 42 is a plan view schematically showing a configuration in which two substrates are simultaneously conveyed.

### DESCRIPTION OF EMBODIMENTS

A conveyance apparatus according to an embodiment is used in a laser irradiation apparatus such as a laser annealing apparatus. The laser annealing apparatus is, for example, an ELA (Excimer Laser Anneal) apparatus that forms an LTPS (Low Temperature Poly-Silicon) film. A conveyance apparatus, a laser irradiation apparatus, a method, and a manufacturing method according to this embodiment will be described hereinafter with reference to the drawings.

### First Embodiment

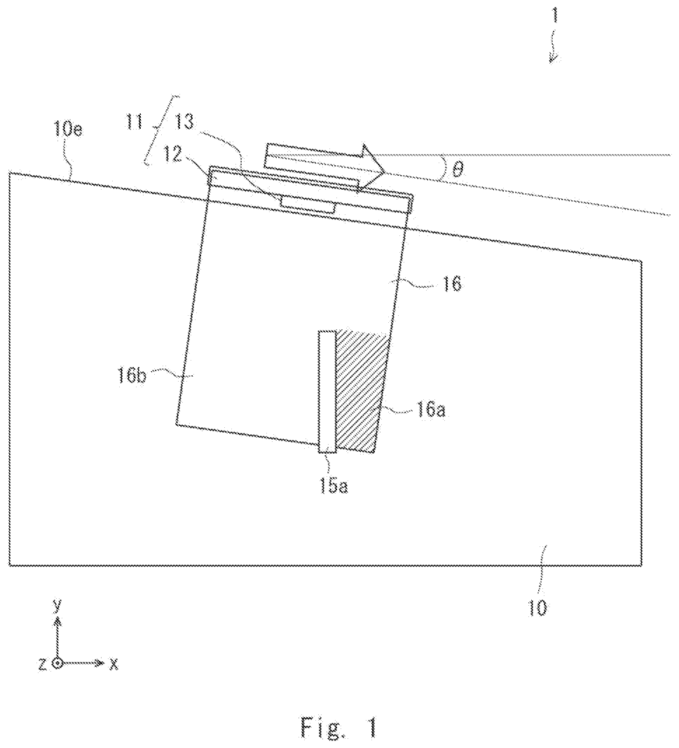

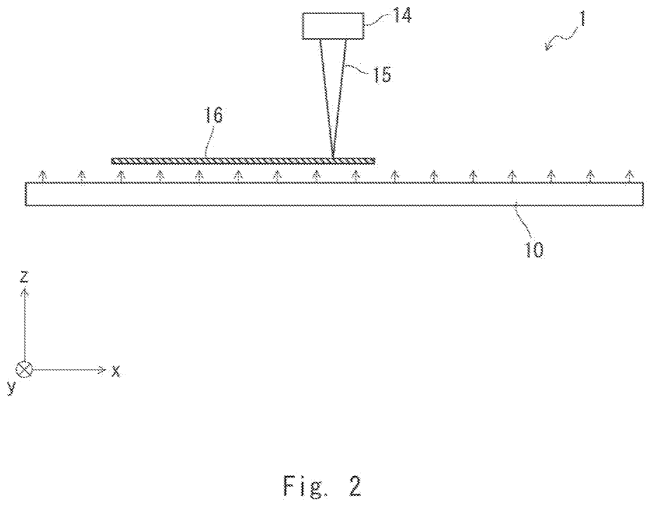

A configuration of a conveyance apparatus and that of a laser irradiation apparatus will be described with reference to FIGS. 1 and 2. FIG. 1 is a plan view schematically showing the configuration of the laser irradiation apparatus 1. FIG. 2 is a side cross-sectional view schematically showing the configuration of the laser irradiation apparatus 1.

Note that in the drawings described below, an xyz three-dimensional orthogonal coordinate system is shown as appropriate for the sake of simplification of the description. The z direction is a vertical direction and the y direction is a direction along a linear irradiation area 15a. The x direction is a direction perpendicular to the z and Y directions. That is, the y direction is the longitudinal direction, i.e., the long-side direction, of the linear irradiation area 15a, and the x direction is the lateral direction, i.e., the short-side direction, perpendicular to the longitudinal direction.

As shown in FIGS. 1 and 2, the laser irradiation apparatus 1 includes a levitation unit 10, a conveyance unit 11, and a laser irradiation unit 14. The levitation unit 10 and the conveyance unit 11 constitute a conveyance apparatus.

As shown in FIG. 2, the levitation unit 10 is configured to eject a gas from its surface. The levitation unit 10 levitates, i.e., floats, an object to be processed 16 over its top surface. The object to be processed 16 is levitated as the gas ejected from the surface of the levitation unit 10 is blown onto the bottom surface of the object to be processed 16. For example, the object to be processed 16 is a glass substrate. When the object to be processed 16 is conveyed, the levitation unit 10 adjusts the levitation height of the object to be processed 16 so that it does not come into contact with other mechanisms (not shown) disposed above the object to be processed 16.

The conveyance unit 11 conveys the levitated object to be processed 16 in the conveyance direction. As shown in FIG. 1, the conveyance unit 11 includes a holding mechanism 12 and a moving mechanism 13. The holding mechanism 12 holds the object to be processed 16. For example, the holding mechanism 12 can be formed by using a vacuum absorption mechanism. The vacuum absorption mechanism is formed by a metal material such as an aluminum alloy. Alternatively, the holding mechanism 12 can be formed of a resin-based material such as a PEEK (polyether ether ketone) material. Absorption grooves, absorption holes, or the like are formed on the top surface of the holding mechanism 12. The holding mechanism 12 may be formed of a porous material.

The holding mechanism 12 (the vacuum absorption mechanism) is connected to an exhaust port (not shown) and the exhaust port is connected to an ejector, a vacuum pump, or the like. Therefore, since a negative pressure for sucking a gas acts on the holding mechanism 12, the object to be processed 16 can be held by using the holding mechanism 12.

Further, the holding mechanism 12 includes a raising/descending mechanism (not shown) for performing an absorption operation. The raising/descending mechanism includes, for example, an air cylinder or an actuator such as a motor. For example, the holding mechanism 12 absorbs the object to be processed 16 in a state where the holding mechanism 12 is raised to an absorption position. Further, the holding mechanism 12 descends to a standby position in a state where the absorption is cancelled, i.e., ceased.

The holding mechanism 12 holds the object to be processed 16 by sucking the surface (the bottom surface) of the object to be processed 16 opposite to the surface (the top surface) thereof to which laser light 15 is applied, i.e., by sucking the surface of the object to be processed 16 that is opposed to the levitation unit 10. Further, the holding mechanism 12 holds the end of the object to be processed 16 in the +y direction (i.e., the end of the object to be processed 16 on the positive side in the y direction).

The moving mechanism 13 included in the conveyance unit 11 is connected to the holding mechanism 12. The moving mechanism 13 is configured to be able to move the holding mechanism 12 in the conveyance direction. The conveyance unit 11 (the holding mechanism 12 and the moving mechanism 13) is disposed at an end of the levitation unit 10 in the +y direction. Further, the object to be processed 16 is conveyed as the moving mechanism 13 moves in the conveyance direction while the holding mechanism 12 is holding the object to be processed 16.

As shown in FIG. 1, for example, the moving mechanism 13 is configured to slide in the conveyance direction at the end of the levitation unit 10 in the +y direction. As the moving mechanism 13 slides in the conveyance direction at the end of the levitation unit 10, the object to be processed 16 is conveyed along the conveyance direction. The conveyance direction is inclined from the x direction. For example, when the angle between the x direction and the conveyance direction is represented by θ, the angle θ is larger than 0°. The angle θ is preferably equal to or smaller than 5°.

Therefore, the levitation unit 10 has a trapezoidal shape having four sides in the plan view. Specifically, the levitation unit 10 has two sides parallel to the y direction of the levitation unit 10, one side parallel to the x direction, and one side inclined from the x direction (hereinafter also referred to as an inclined side 10e).

Note that the conveyance speed of the object to be processed 16 can be controlled by controlling the moving speed of the moving mechanism 13. The moving mechanism 13 includes, for example, an actuator such as a motor, a liner guide mechanism, an air bearing, etc. (not shown).

The object to be processed 16 is irradiated with laser light 15. Note that the irradiation area 15a of the laser light 15 in the object to be processed 16 has a line-like shape whose longitudinal direction is parallel to the y direction. That is, the longitudinal direction of the irradiation area 15a is parallel to the y direction, and the crosswise direction thereof is parallel to the x direction.

For example, the laser irradiation unit 14 includes an excimer laser light source or the like that generates laser light. Further, the laser irradiation unit 14 includes an optical system that guides the laser light to the object to be processed 16. For example, the laser irradiation unit 14 includes a cylindrical lens for forming the linear irradiation area 15a. The object to be processed 16 is irradiated with line-shaped laser light, specifically, the laser light 15 (a line beam) whose focal point extends, i.e., stretches, in the y direction.

The object to be processed 16 is, for example, a glass substrate in which an amorphous film (an amorphous silicon film 16b) is formed. The amorphous film can be crystallized by irradiating the amorphous film with laser light 15 and thereby performing an annealing process. For example, an amorphous silicon film 16b can be converted into a polycrystalline silicon film (a polysilicon film 16a).

The laser irradiation apparatus 1 conveys the object to be processed 16 in the conveyance direction by holding the bottom surface of the object to be processed 16 using the conveyance unit 11 while levitating the object to be processed 16 using the levitation unit 10. Note that when the object to be processed 16 is conveyed, the conveyance unit 11 included in the laser irradiation apparatus 1 conveys the object to be processed 16 while the conveyance unit 11 is holding a part of the object to be processed 16 that does not overlap the irradiation area 15a in a plan view, i.e., as viewed in the z-direction. That is, as shown in FIG. 1, when the object to be processed 16 is conveyed in the conveyance direction, the part of the object to be processed 16 at which the conveyance unit 11 holds the object to be processed 16 (which corresponds to the position of the holding mechanism 12) does not overlap the irradiation area 15a.

For example, a planar shape of the object to be processed 16 is a quadrangle (a rectangular) having four sides and the conveyance unit 11 (the holding mechanism 12) holds only one of the four sides of the object to be processed 16. Further, the conveyance unit 11 (the holding mechanism 12) holds a part of the object to be processed 16 that is not irradiated with laser light in a period during which the object to be processed 16 is being conveyed.

By the above-described configuration, it is possible to position the part of the object to be processed 16 at which the conveyance unit 11 holds the object to be processed 16 (which corresponds to the position of the holding mechanism 12) and the irradiation area 15a away from each other. The irradiation area 15a corresponds to roughly a half of the object to be processed 16 in the −y direction, and the conveyance unit 11 holds the end the object to be processed 16 in the +y direction. It is possible to increase the distance between the place near the holding mechanism 12 where the object to be processed 16 is bent widely and the irradiation area 15a. Therefore, it is possible to reduce the effect of the bending of the object to be processed 16 caused by the holding mechanism 12 when laser light is applied to the object to be processed 16.

In the y direction, the length of the irradiation area 15a is about half the length of the object to be processed 16. Therefore, when the object to be processed 16 passes the laser irradiation place 15a once, the amorphous silicon film in substantially a half of the area of the object to be processed 16 is crystallized. Then, after the object to be processed 16 is rotated about the z-axis by 180 degrees by a rotation mechanism (not shown), the conveyance unit 11 conveys the object to be processed 16 in the −x direction. Alternatively, after the rotated object to be processed 16 is conveyed in the −x direction, the conveyance unit 11 may convey the object to be processed 16 again in the +x direction. Then, when the object to be processed 16 is conveyed in the −x direction or when the object to be processed 16 is conveyed in the +x direction again after the rotation of 180 degrees, laser light is applied to the object to be processed 16. In this way, the object to be processed 16 passes through the laser irradiation place 15a, and the amorphous silicon film in the remaining half of the object to be processed 16 is crystallized. By making the object to be processed 16 perform a reciprocating movement as described above, the amorphous silicon film is converted into a polycrystalline silicon film over the substantially entire area of the object to be processed 16.

Further, the conveyance direction is inclined from the x direction, which is perpendicular to the linear irradiation area 15a. That is, the object to be processed 16 is conveyed in the conveyance direction inclined from the edge of the rectangular object to be processed 16. By inclining the conveyance direction from the x direction in the plan view, it is possible to perform conveyance of a substrate suitable for a laser irradiation process. Therefore, it is possible to appropriately perform a process for crystallizing a silicon film, and thereby to improve the display quality. By the above-described configuration, for example, it is possible to prevent an occurrence of a moire.

Assume that, for example, the object to be processed 16 is a glass substrate for an organic EL (Electro-Luminescence) display device. When the display area of the organic EL display device is rectangular, the edges of the display area are parallel to the edges of the object to be processed 16. That is, the organic EL display device has a rectangular display area whose short sides are parallel to the x and y directions. When the conveyance direction is parallel to the x direction, laser light is applied to the object to be processed 16 in a state where the direction in which pixels are arranged is parallel to the irradiation area 15a.

As shown in this embodiment, it is possible to appropriately perform a laser irradiation process by inclining the conveyance direction from the x direction. The moving mechanism 13 moves the holding mechanism 12 in the conveyance direction inclined from the x direction perpendicular to the longitudinal direction of the linear irradiation area 15a in the plan view so as to change the irradiation place of the laser light in the object to be processed 16. In this way, it is possible to appropriately perform a process for crystallizing a silicon film. For example, it is possible to prevent an occurrence of a moire and thereby to improve the display quality.

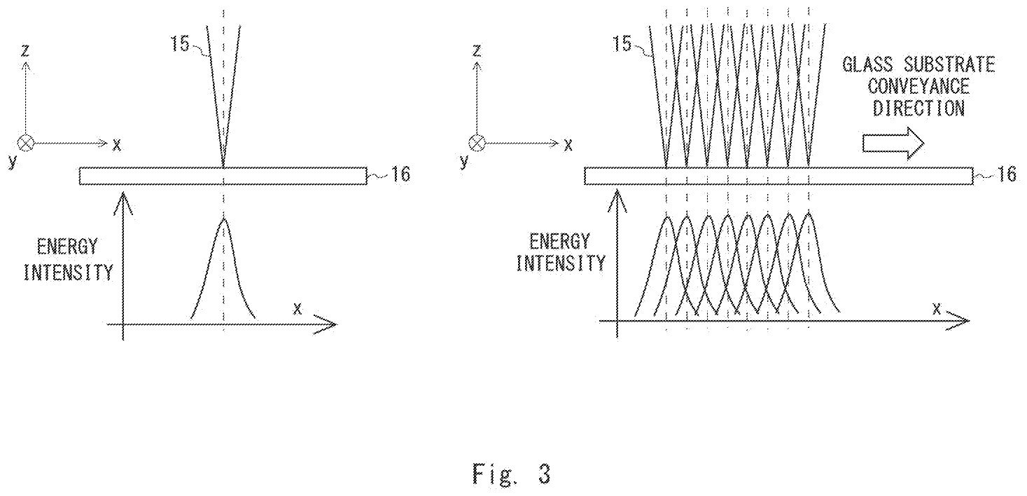

This feature will be described in detail. FIG. 3 is a diagram for explaining a distribution of energy intensity when pulsed laser light is applied. Here, it is assumed that the laser light 15 is pulsed laser light having a constant repetition frequency. Further, the pulsed laser light is applied to the object to be processed 16 while the object to be processed 16 is being conveyed.

The laser light 15 has a distribution of intensity as shown in FIG. 3. For example, in FIG. 3, the distribution of intensity of the laser light 15 is a Gaussian distribution. Further, the object to be processed 16 is conveyed so that consecutive pulsed laser lights partially overlap with one another. That is, the conveyance distance corresponding to the repetition frequency of the pulsed laser light is shorter than the spot width in the crosswise direction of the laser light. In the object to be processed 16, a spot of given one pulse of the laser light 15 partially overlaps with that of the next one pulse thereof.

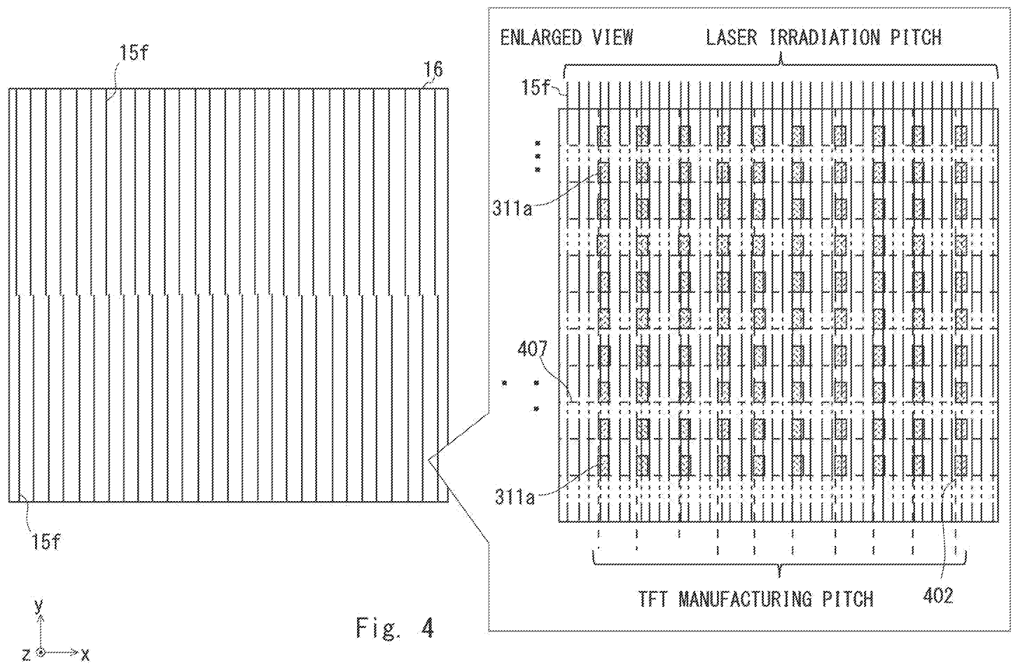

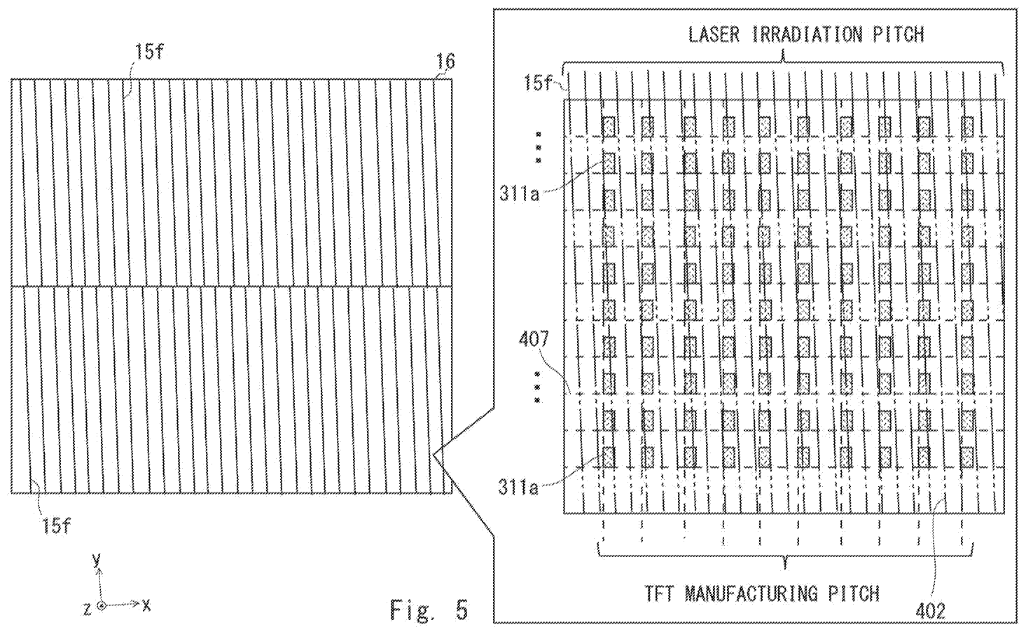

Here, it is assumed that the object to be processed 16 is a TFT array substrate. The relation between the manufacturing pitch of TFTs and the irradiation pitch of laser will be described with reference to FIGS. 4 and 5. Each of FIGS. 4 and 5 is a plan view schematically showing a laser irradiation pitch in an object to be processed 16. Further, each of FIGS. 4 and 5 shows an enlarged view of the object to be processed 16. FIG. 4 shows a comparative example in which the direction perpendicular to the line-shaped laser light is parallel to the conveyance direction. FIG. 5 shows an example of this embodiment in which the direction perpendicular to the line-shaped laser light is inclined from the conveyance direction.

In the comparative example shown in FIG. 4, the edges of the object to be processed 16 are parallel to the line-shaped laser light. The edges of the object to be processed 16 are parallel to the x or y direction. Each of irradiation lines 15f of the laser light is a straight line indicating the center of the irradiation area 15a of the laser light, and is parallel to the longitudinal direction of the irradiation area. In FIG. 4, the irradiation lines 15f are parallel to the y direction, and the irradiation lines 15f are perpendicular to the conveyance direction of the object to be processed 16. Since the conveyance speed of the object to be processed 16 is constant, the irradiation lines 15f are arranged at equal intervals. The interval of the irradiation lines 15f is defined as the irradiation pitch. The irradiation pitch is determined by the repetition frequency of the pulsed laser light and the conveyance speed.

Each of gate electrodes 402 and source electrodes 407 is formed parallel to the edges of the object to be processed 16. In FIG. 4, the gate electrodes 402 are parallel to the y direction and also parallel to the source electrodes 407. TFTs 313a are arranged along the x and y directions. The manufacturing pitch of TFTs corresponds to the interval between the gate electrodes 402.

In the x direction, the laser irradiation pitch is different from the manufacturing pitch of the TFTs. When the two different pitches overlap with each other, a striped pattern, i.e., a moire, visually appears due to the undulation (beat) of figures. Note that, strictly speaking, due to a small deviation in the starting position of the laser irradiation, the position of the irradiation line of the second laser irradiation (the lower half surface in FIG. 4) is deviated from that of the first laser irradiation line (the upper half surface in FIG. 4).

In the example of this embodiment shown in FIG. 5, the irradiation lines 15f are inclined from the conveyance direction of the object to be processed 16. Since the object to be processed 16 is conveyed in the direction perpendicular to the longitudinal direction of the laser light, the periodicity of the shape that appears in the same direction in the comparative example is eliminated. As a result, a moire become less likely to be visible. As described above, by conveying the object to be processed 16 in a direction inclined from the direction perpendicular to the longitudinal direction of the line-shaped laser light, the occurrence of a moire can be prevented.

Note that, depending on the angle of the irradiation lines 15f, there are cases where the moire is not eliminated or a different type of moire occurs. In such a case, the angle of the irradiation lines 15f may be adjusted according to the manufacturing pitch of the TFTs and the like. Note that, strictly speaking, due to a small deviation in the starting position of the laser irradiation, the position of the irradiation line of the second laser irradiation (the lower half surface in FIG. 4) is deviated from that of the first laser irradiation line (the upper half surface in FIG. 4).

In the conveyance method according to this embodiment, the object to be processed 16 is conveyed in order to irradiate the object to be processed 16 with line-shaped laser light 15. The levitation unit 10 levitates, i.e., floats, the object to be processed 16 over its top surface. The holding mechanism 12 holds the object to be processed 16. The holding mechanism 12 is moves in a direction inclined from the direction perpendicular to the longitudinal direction of the line-shaped laser light in the plan view so as to change the irradiation place of the laser light 15 in the object to be processed 16.

### Second Embodiment

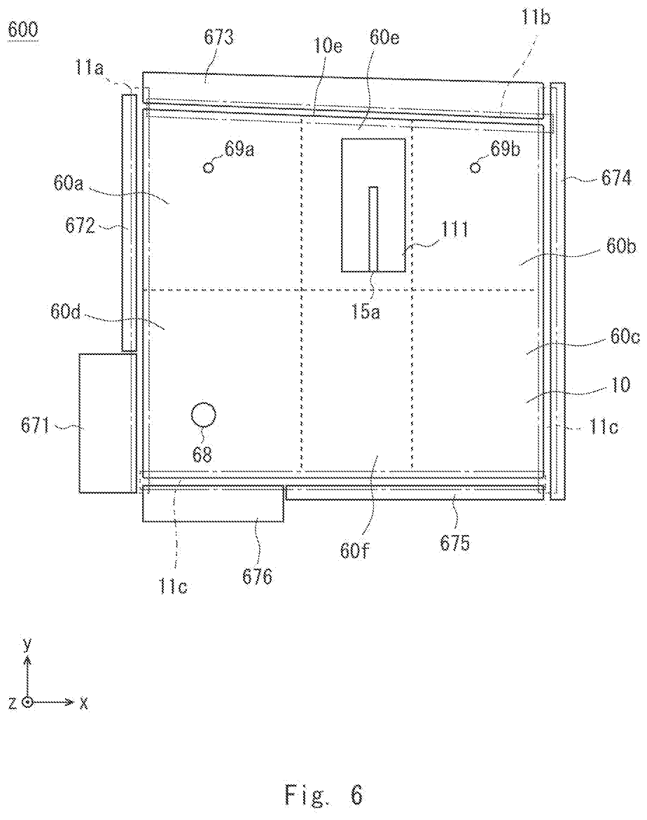

A conveyance apparatus according to a second embodiment will be described hereinafter with reference to FIG. 6. FIG. 6 is a plan view schematically showing a conveyance apparatus 600. Note that descriptions of the components, structures, and the like of the second embodiment that are same as those of the first embodiment are omitted as appropriate.

The conveyance apparatus 600 includes a levitation unit 10 and end levitation units 671 to 676. The levitation unit 10 levitates a substrate (not shown in FIG. 6), which is the object to be processed. Similarly to the first embodiment, the levitation unit 10 has a trapezoidal shape in the plan view. The levitation unit 10 has two sides parallel to the y direction of the levitation unit 10, one side parallel to the x direction, and one side inclined from the x direction (hereinafter also referred to as an inclined side 10e). The angle between the inclined side 10e and the x direction is preferably larger than 0° and not larger than 5°.

Hereinafter, for the sake of explanation, the levitation unit 10 is divided into six areas 60a to 60f in the plan view. Specifically, the levitation unit 10 includes a first area 60a to a fourth area 60d, a process area 60e, and a passage area 60f. The first area 60a is a trapezoidal area that includes the corner on the −x side and the +y side (the upper-left corner in FIG. 6). The second area 60b is a trapezoidal area that includes the corner on the +x side and the +y side (the upper-right corner in FIG. 6). The third area 60c is a trapezoidal area that includes the corner on the +x side and the −y side (the lower-right corner in FIG. 6). The fourth area 60d is a trapezoidal area that includes the corner on the −x side and the −y side (the lower-left corner in FIG. 6).

The process area 60e is a trapezoidal area located between the first and second areas 60a and 60b. The process area 60e is an area including the irradiation area 15a to which laser light is applied. The passage area 60f is a rectangular area located between the third and fourth areas 60c and 60d.

The half of the area of the levitation unit 10 on the +y side (the upper half area in FIG. 6) is composed of, in the order from the −x side (from the left side in FIG. 6), the first area 60a, the process area 60e, and the second area 60b. The half of the area of the levitation unit 10 on the −y side (the lower half area in FIG. 6) is composed of, in the order from the +x side, the third area 60c, the passage area 60f, and the fourth area 60d.

The levitation unit 10 includes a rotation mechanism 68, and alignment mechanisms 69a and 69b. The rotation mechanism 68 rotates the substrate. Each of the alignment mechanisms 69a and 69b aligns the substrate. The alignment mechanisms 69a and 69b are provided in the first and second areas 60a and 60b, respectively. The rotation mechanism 68 is provided in the fourth area 60d. The operations of the rotation mechanism 68, the alignment mechanisms 69a and 69b, and the like will be described later.

The end levitation units 671 to 676 are disposed outside the levitation unit 10. The end levitation units 671 to 676 are arranged along the periphery of the trapezoidal levitation unit 10. The end levitation units 671 to 676 are arranged along the edges of the levitation unit 10. In the plan view, the end levitation units 671 to 676 are arranged so as to surround the periphery of the levitation unit 10.

The end levitation units 671 and 672 are disposed on the −x side of the levitation unit 10. The end levitation unit 673 is disposed on the +y side of the levitation unit 10. The end levitation unit 674 is disposed on the +x side of the levitation unit 10. The end levitation units 675 and 676 are disposed on the −y side of the levitation unit 10. Note that at least one of the end levitation units 671, 672, 673, 674, 675 and 676 can be omitted. For example, the holding mechanism 12 holds an end of the substrate 100. The levitation unit 10 levitates the remaining part of the substrate, i.e., part of the substrate other than the end thereof. By doing so, it is possible to levitate the substrate without a levitation unit(s) 10 disposed near the levitation unit 10.

The end levitation units 671 and 672 are disposed along the edge of the levitation unit 10 on the −x side. That is, each of the end levitation units 671 and 672 is disposed along the y direction. Further, the width of the end levitation unit 671 in the x direction is wider than that of the end levitation unit 672. The end levitation unit 671 is disposed on the −y side of the end levitation unit 672.

The end levitation unit 673 is disposed along the edge of the levitation unit 10 on the +y side. That is, the end levitation unit 673 is disposed along the inclined side 10e of the levitation unit 10. The end levitation unit 674 is disposed along the edge of the levitation unit 10 on the +x side. That is, each of the end levitation units 674 is provided along the y direction.

The end levitation units 675 and 676 are disposed along the edge of the levitation unit 10 on the −y side. That is, each of the end levitation units 675 and 676 is provided along the x direction. Further, the width of the end levitation unit 676 in the y direction is wider than that of the end levitation unit 675. The end levitation unit 676 is disposed on the −x side of the end levitation unit 675.

A conveyance unit 11a is provided between the levitation unit 10 and the end levitation unit 671. A part of the conveyance unit 11a is disposed between the levitation unit 10 and the end levitation unit 672. The conveyance unit 11a is formed along the y direction. The conveyance unit 11a conveys the substrate in the +y direction. That is, the conveyance unit 11a conveys the substrate 100 from the fourth area 60d toward the first area 60a.

A conveyance unit 11b is provided between the levitation unit 10 and the end levitation unit 673. The conveyance unit 11b is formed along the inclined side 10e. The conveyance unit 11b conveys the substrate in a direction parallel to the inclined side 10e. That is, the conveyance unit 11b conveys the substrate 100 from the first area 60a toward the second area 60b.

A conveyance unit 11c is provided between the levitation unit 10 and the end levitation unit 674. The conveyance unit 11c is formed along the y direction. The conveyance unit 11c conveys the substrate 100 in the −y direction. That is, the conveyance unit 11c conveys the substrate 100 from the second area 60b toward the third area 60c.

A conveyance unit 11d is provided between the levitation unit 10 and the end levitation unit 675. A part of the conveyance unit 11d is disposed between the levitation unit 10 and the end levitation unit 676. The conveyance unit 11d is formed along the x direction. The conveyance unit 11a conveys the substrate in the −x direction. That is, the conveyance unit 11d conveys the substrate from the third area 60c toward the fourth area 60d.

Note that each of the conveyance units 11a to 11d includes a holding mechanism 12 and a moving mechanism 13 as in the case of the first embodiment. The operations of the holding mechanism 12 and the moving mechanism 13 will be described later.

Similarly to the first embodiment, the longitudinal direction of the irradiation area 15a of the laser light is parallel to the y direction. That is, a linear irradiation area 15a whose longitudinal direction is parallel to the y direction is formed. The laser light is applied to the substrate while the substrate is being conveyed in the direction parallel to the inclined side 10e. A laser irradiation process is performed while the substrate is moving from the first area 60a to the second area 60b. In this embodiment, similarly to the first embodiment, an amorphous silicon film is converted into a polysilicon film by applying laser light emitted from a laser generation apparatus to the substrate.

Note that, in the levitation unit 10, a precision levitation unit 111 is disposed in the irradiation area 15a and on the periphery thereof. The accuracy of the levitation height by the precision levitation unit 111 is higher than those of semi-precision levitation units and rough levitation units. Therefore, in the process area 60e, which includes the irradiation area 15a, the laser light is applied to the object to be processed which is being levitated with higher accuracy of the levitation height than the accuracy in the other areas 60a, 60b, 60c, 60d and 60f. In this way, it is possible to apply the laser light to the object to be processed in a stable manner. Further, the areas other than the irradiation area 15a, such as the passage area 60f, the third area 60c, and the fourth area 60d, are manufactured without using an expensive precision levitation unit 111. Therefore, the cost of the apparatus can be reduced.

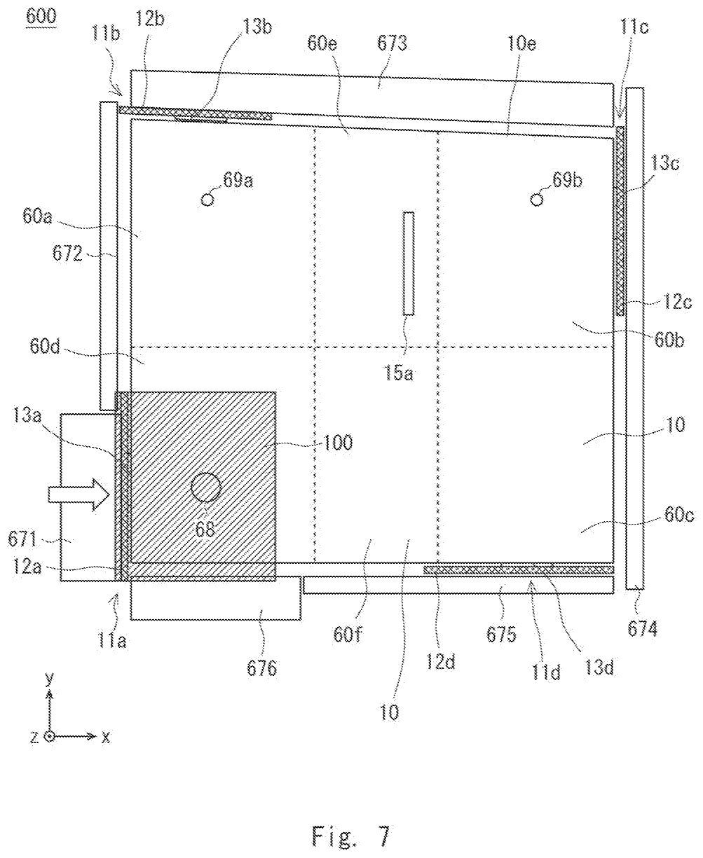

Next, a procedure in a conveyance method using the levitation unit 10 will be described with reference to FIGS. 7 to 13. In this example, the fourth area 60d is used as a place where the substrate 100 is carried in and carried out. Further, the substrate 100 carried into the fourth area 60d is conveyed from one area to another in the order of the first area 60a, the process area 60e, the second area 60b, the third area 60c, the passage area 60f, and the fourth area 60d. That is, the substrate 100 moves round (circulates) along the edges of the levitation unit 10, i.e., is conveyed so as to go round along the four edges of the levitation unit. Note that the substrate 100 moves round twice so that the entire area of the substrate 100 is irradiated with the laser light. That is, the substrate 100 is conveyed so that it moves round twice over the levitation unit 10. By doing so, substantially the entire surface of the substrate 100 is irradiated with the laser light.

The above-described process will be described hereinafter in detail along the procedure in the conveyance method. As shown in FIG. 7, the substrate 100 is carried into the fourth area 60d. The substrate 100 carried into the fourth area 60d is being levitated by the levitation unit 10, and the end levitation units 671, 672 and 676. That is, the end of the substrate 100 on the −x side is being levitated by the end levitation units 671 and 672, and the central part thereof is being levitated by the levitation unit 10. The end of the substrate 100 on the −y side is being levitated by the end levitation unit 676. Further, the holding mechanism 12a of the conveyance unit 11a holds the substrate 100.

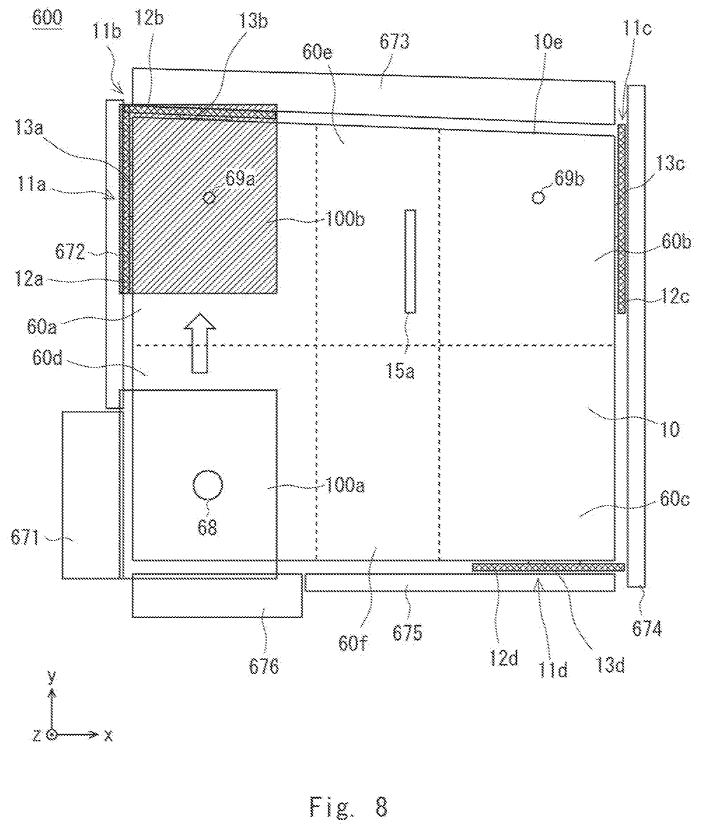

Next, as shown in FIG. 8, the substrate 100a, which is located in the fourth area 60d, is conveyed to the first area 60a. In FIG. 8, the substrate that has been moved to the first area 60a is shown as a substrate 100b. The holding mechanism 12a of the conveyance unit 11a is holding the substrate 100a. Then, a moving mechanism 13a moves the holding mechanism 12a in the +y direction, so that the substrate 100a is moved from the fourth area 60d to the first area 60a (indicted by an outlined arrow in FIG. 8).

Note that, in the xy-plane view, the holding mechanism 12a moves in the +y direction through the gap between the levitation unit and the end levitation unit 671. Further, in the xy-plane view, the holding mechanism 12a moves in the +y direction though the gap between the levitation unit 10 and the end levitation unit 672. Therefore, the substrate 100b is being levitated by the levitation unit 10, and the end levitation units 672 and 673. That is, the end of the substrate 100b on the −x side is being levitated by the end levitation unit 672, and the central part thereof is being levitated by the levitation unit 10. The end of the substrate 100b on the +y side is being levitated by the end levitation unit 673.

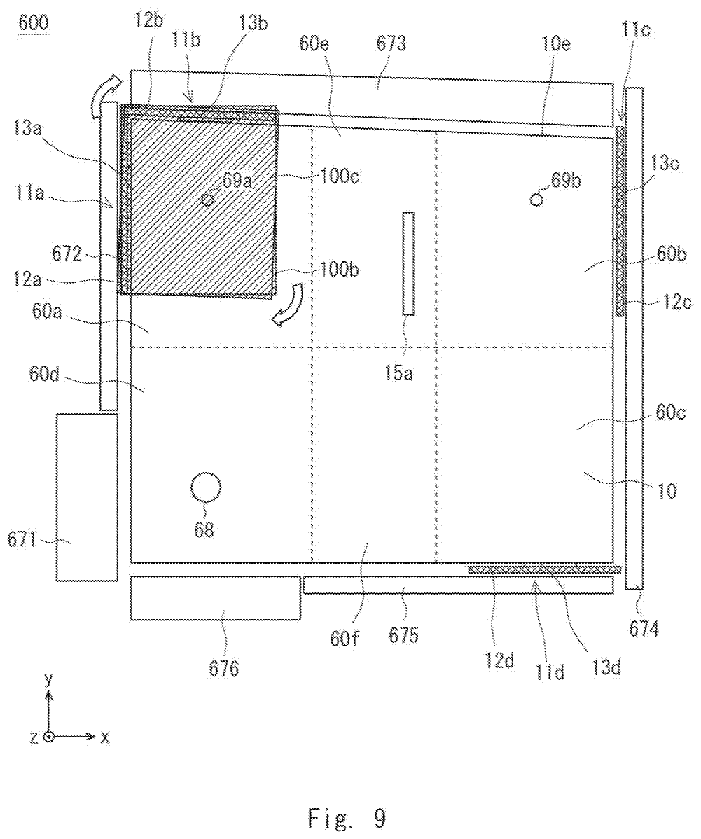

Next, as shown in FIG. 9, the alignment mechanism 69a aligns the position and the angle of the substrate 100b, which has been conveyed to the first area 60a. For example, the position and the rotation angle of the substrate 100 may be slightly deviated due to the carrying-in operation, the conveying operation, and/or the rotating operation of the substrate 100. The alignment mechanism 69a compensates for the deviation in the position and/or the rotation angle of the substrate. In this way, it is possible to accurately control the irradiation place of the laser light in the substrate 100.

For example, the alignment mechanism 69a can be moved in the y direction and can be rotated around the z-axis. Further, the alignment mechanism 69a can be moved in the z direction. For example, the alignment mechanism 69a includes an actuator(s) such as a motor(s). The amounts of deviations in the position and the angle of the substrate 100b are obtained from an image thereof taken by a camera or the like. The alignment mechanism 69a performs alignment based on these deviation amounts.

The alignment mechanism 69a is disposed directly below the central part of the substrate 100b. The alignment mechanism 69a holds the substrate 100b. The alignment mechanism 69a may adsorb and hold the substrate 100b in a manner similar to that of the holding mechanism 12. The holding mechanism 12a releases, i.e., ceases, the holding of the substrate 100b. In this way, the substrate 100b is handed over from the holding mechanism 12a to the alignment mechanism 69a.

Then, the alignment mechanism 69a rotates the substrate 100b around the z-axis (indicted by an outlined arrow in FIG. 9). The alignment mechanism 69a rotates the substrate 100b so that the edge of the substrate 100b becomes parallel to the inclined side 10e of the levitation unit 10. The substrate after the rotation is shown as a substrate 100c. For example, the alignment mechanism 69a rotates the substrate 100 around the z-axis by about 5°. The edge of the substrate 100c is parallel to the inclined side 10e of the levitation unit 10. Then, after the alignment is finished, the holding mechanism 12b of the conveyance unit 11b holds the substrate 100b, and the alignment mechanism 69a releases the holding thereof. As a result, the substrate 100c is handed over from the alignment mechanism 69a to the holding mechanism 12b of the conveyance unit 11b.

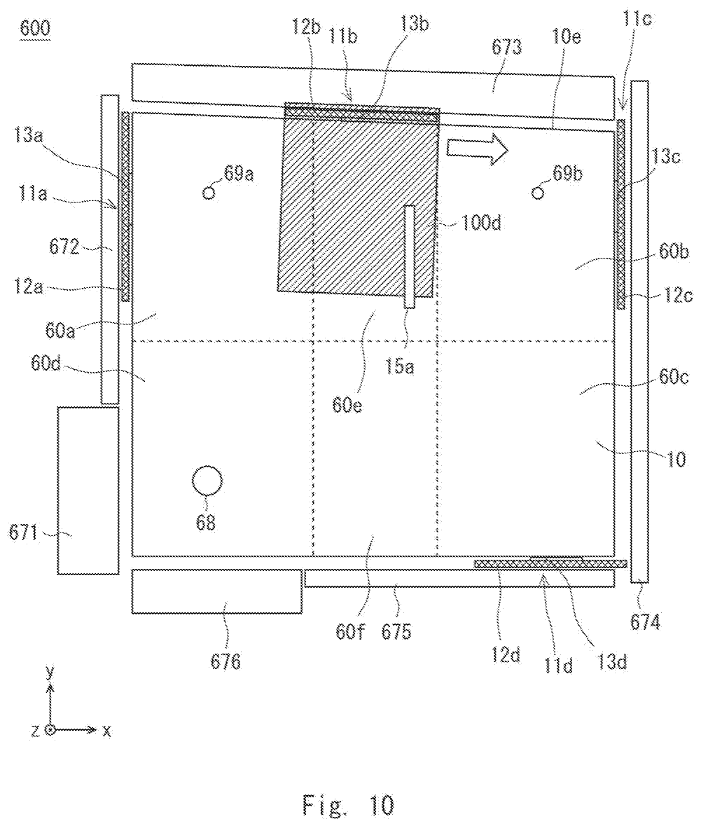

Next, as shown in FIG. 10, the conveyance unit 11b moves the substrate 100d. As a result, the substrate 100d passes through the process area 60e. In this process, in the xy-plane view, the holding mechanism 12b moves in the direction parallel to the inclined side 10e through the gap between the levitation unit 10 and the end levitation unit 673. In this way, substantially a half of the area of the substrate 100d passes through the irradiation area 15a. The laser light is applied to the substrate 100d, which is moving in the inclined direction inclined from the x direction perpendicular to the irradiation area 15a.

In the xy-plane view, the holding mechanism 12b moves in the direction parallel to the inclined side 10e through the gap between the levitation unit 10 and the end levitation unit 673. Therefore, the substrate 100d is being levitated by the levitation unit 10 and the end levitation unit 673. That is, the end of the substrate 100d on the +y side is being levitated by the end levitation unit 673, and the central part thereof is being levitated by the levitation unit 10. A laser irradiation process is performed while the substrate is moving from the first area 60a to the second area 60b.

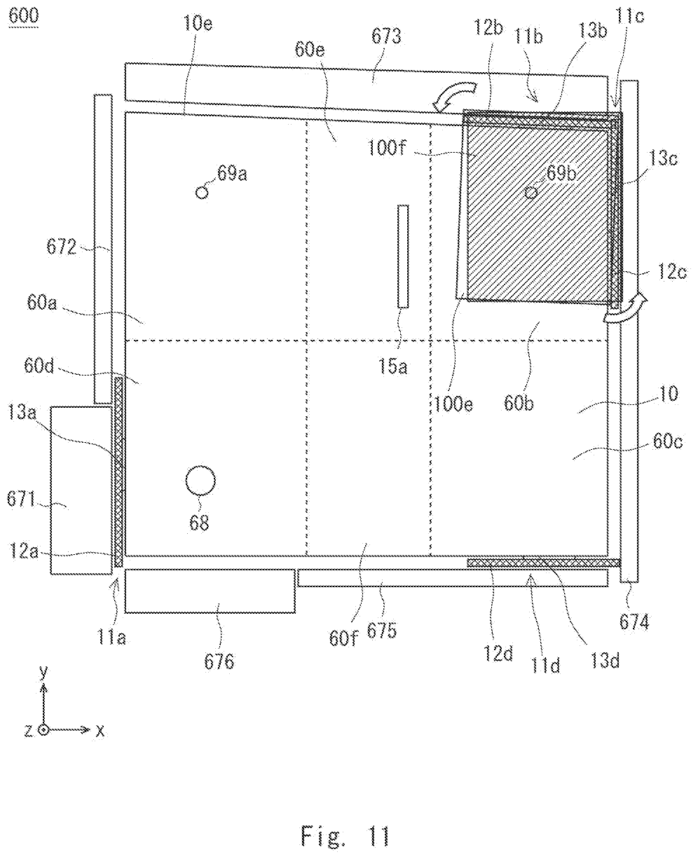

Next, as shown in FIG. 11, when the substrate 100e has moved to the second area 60b, the alignment mechanism 69b aligns the substrate 100e. In this process, the alignment mechanism 69b rotates the substrate 100e (indicted by an outlined arrow in FIG. 11). In FIG. 11, the substrate after the rotation is shown as a substrate 100f.

The alignment mechanism 69b is disposed directly below the central part of the substrate 100e. The alignment mechanism 69b holds the substrate 100e. The alignment mechanism 69b may adsorb and hold the substrate 100e in a manner similar to that of the holding mechanism 12. Further, the holding mechanism 12b releases the holding of the substrate 100e. The substrate 100e is handed over from the holding mechanism 12b of the conveyance unit 11b to the alignment mechanism 69b.

The alignment mechanism 69b rotates the substrate 100e around the z-axis (indicted by an outlined arrow in FIG. 11). The alignment mechanism 69a rotates the substrate 100e so that the edge of the substrate 100e becomes parallel to the inclined side 10e of the levitation unit 10. After the rotation, the edges of the substrate 100f are parallel to the x or y direction. Then, after the alignment is finished, the holding mechanism 12c of the conveyance unit 11c holds the substrate 100f, and the alignment mechanism 69b releases the holding thereof. As a result, the substrate 100f is handed over from the alignment mechanism 69b to the holding mechanism 12c of the conveyance unit 11c.

The substrate 100e is being levitated by the levitation unit 10, and the end levitation units 673 and 674. That is, the end of the substrate 100e on the +y side is being levitated by the end levitation unit 673. The end of the substrate 100e on the +x side is being levitated by the end levitation unit 674, and the central part thereof is being levitated by the levitation unit 10.

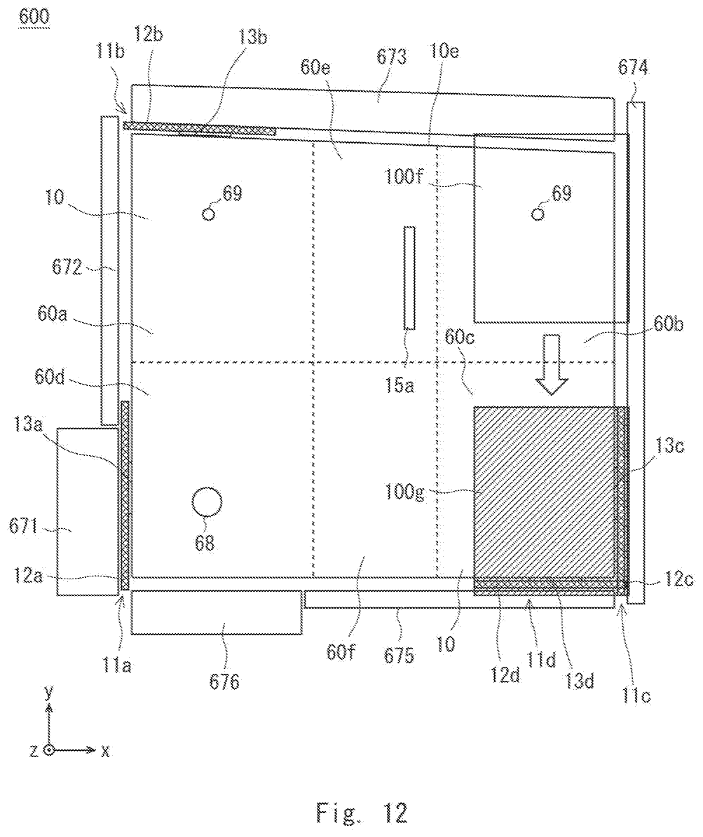

Next, as shown in FIG. 12, the substrate 100f, which is located in the second area 60b, is conveyed to the third area 60c. The substrate that has moved to the third area 60c is shown as a substrate 100g. In FIG. 12, the holding mechanism 12c of the conveyance unit 11c is holding the substrate 100f. Then, the moving mechanism 13c moves the holding mechanism 12c in the −y direction, so that the substrate 100f is moved from the second area 60b to the third area 60c (indicted by an outlined arrow in FIG. 12).

In this process, in the xy-plane view, the holding mechanism 12c moves in the −y direction through the gap between the levitation unit and the end levitation unit 674. Therefore, the substrate 100e is being levitated by the levitation unit 10, and the end levitation units 674 and 675. The end of the substrate 100e on the +x side is being levitated by the end levitation unit 674, and the central part thereof is being levitated by the levitation unit 10. The end of the substrate 100e on the −y side is being levitated by the end levitation unit 675.

Then, the holding mechanism 12d of the conveyance unit 11d holds the substrate 100g, and the holding mechanism 12c releases the holding thereof. As a result, the substrate 100g is handed over from the holding mechanism 12c of the conveyance unit 11c to the holding mechanism 12d of the conveyance unit 11d.

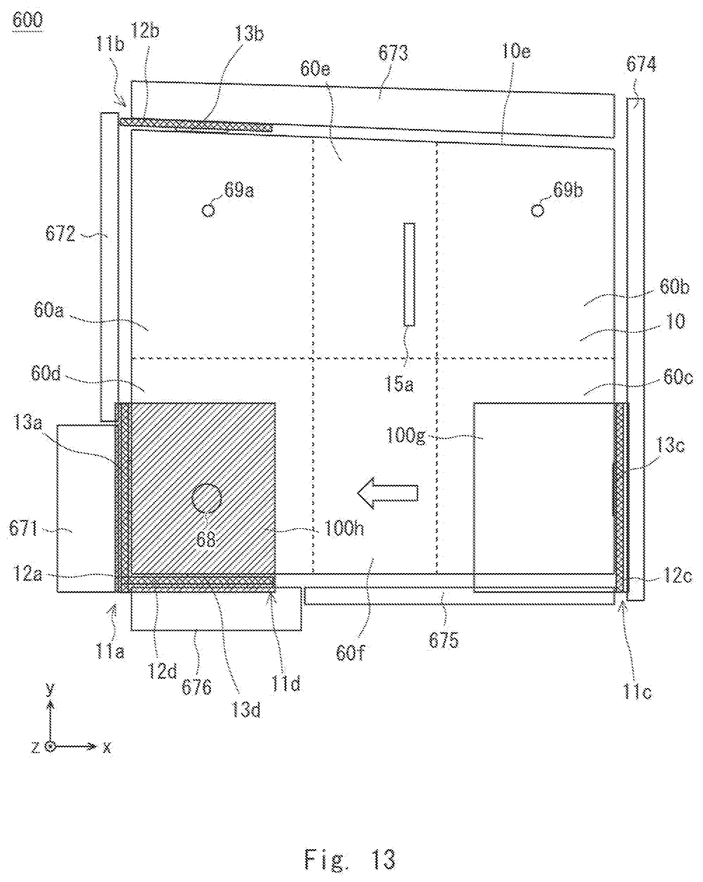

Next, as shown in FIG. 13, the substrate 100g, which is located in the third area 60c, is conveyed to the fourth area 60d. The substrate that has moved to the fourth area 60d is shown as a substrate 100h. In FIG. 13, the holding mechanism 12d of the conveyance unit 11d is holding the substrate 100g. Then, the moving mechanism 13d moves the holding mechanism 12d in the −x direction, so that the substrate 100f is moved from the third area 60c to the fourth area 60d (indicted by an outlined arrow in FIG. 13).

Note that, in the xy-plane view, the holding mechanism 12d moves in the −x direction through gap between the levitation unit 10 and the end levitation unit 675. In the xy-plane view, the holding mechanism 12d moves in the −x direction through the gap between the levitation unit 10 and the end levitation unit 676. Therefore, the substrate 100h is being levitated by the levitation unit 10 and the end levitation unit 676. The end of the substrate 100h on the −y side is being levitated by the end levitation unit 676, and the central part thereof is being levitated by the levitation unit 10. The end of the substrate 100h on the −x side is being levitated by the end levitation unit 671.

In this way, the substrate 100, which was originally disposed in the fourth area 60d, is moved from one area to another in the order of the first area 60a, the process area 60e, the second area 60b, the third area 60c, the passage area 60f, and the fourth area 60d. That is, the substrate 100 moves round along the edges of the levitation unit 10.

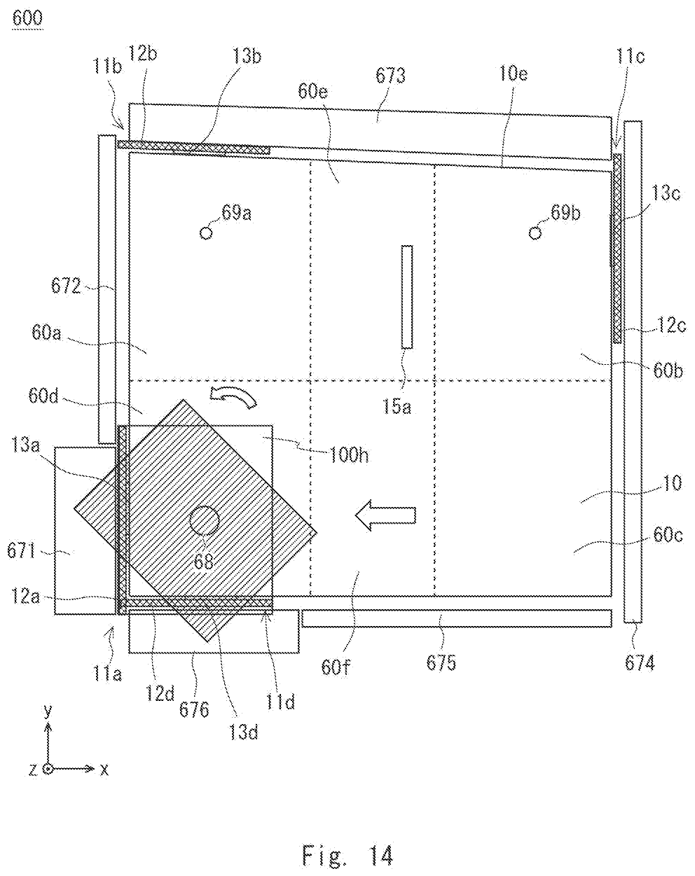

Next, as shown in FIG. 14, the rotation mechanism 68 rotates the substrate 100h around the z-axis by 180°. That is, the substrate 100h is handed over from the holding mechanism 12d to the rotation mechanism 68. After the rotation mechanism 68 rotates the substrate 100h, the substrate 100h is handed over from the rotation mechanism 68 to the holding mechanism 12d.

Similarly to the above-described processes, the conveyance units 11a to 11d move the substrate 100h again from one area to another in the order of the first area 60a, the process area 60e, the second area 60b, the third area 60c, the passage area 60f, and the fourth area 60d. That is, as shown in FIGS. 7 to 13, the substrate 100 moves round along the edges of the levitation unit 10.

In this example, the rotation mechanism 68 rotates the substrate 100h by 180°. When the substrate 100e passes through the process area 60e for the second time, the laser light is applied to the remaining half of the area of the substrate that was not irradiated with the laser light in the first passage. As described above, the substrate 100 moves round twice along the edges of the levitation unit 10. Since the substrate 100 is rotated 180° between the first laser irradiation and the second laser irradiation, substantially the entire surface of the substrate 100 is irradiated with the laser light. Note that the place in which the substrate 100 is rotated is not limited to the first area 60a. For example, the rotation may be performed in the second area 60b, the third area 60c, the fourth area 60d, or the like.

In this embodiment, the moving mechanism 13b also conveys the holding mechanism 12b in a direction inclined from the x direction perpendicular to the irradiation area 15a. Therefore, it is possible to appropriately perform a process for crystallizing a silicon film. For example, it is possible to prevent an occurrence of a moire and thereby to improve the display quality.

### (Holding Mechanism 12)

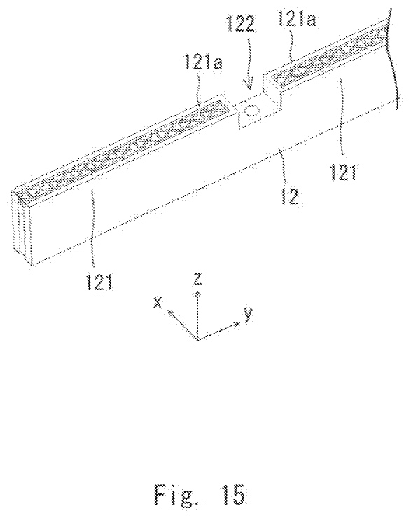

Next, an example of the holding mechanism 12 will be described with reference to FIG. 15. FIG. 15 is a perspective view schematically showing a part of a holding mechanism 12. FIG. 15 shows the holding mechanism 12 which moves in the y direction as in the case of the holding mechanism 12c shown in FIG. 13. FIG. 15 shows a structure of an end of the holding mechanism 12 on the −y side.

The holding mechanism 12 includes a plurality of absorption cells 121. The plurality of absorption cells 121 are arranged along the conveyance direction. A recess 122 is formed between two absorption cells 121. The holding mechanism 12 is formed of, for example, a metal material such as aluminum. For example, the plurality of absorption cells 121 can be integrally formed by an aluminum alloy such as A5052.

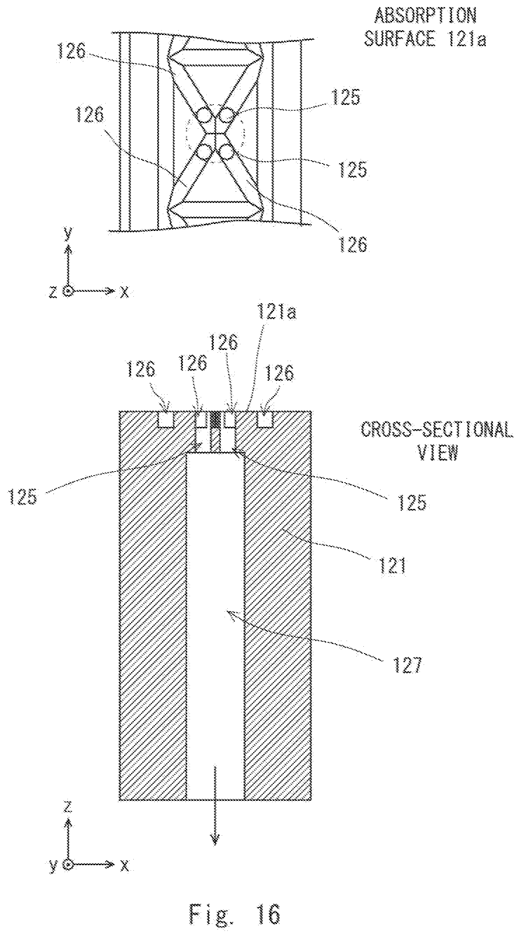

The top surfaces of the absorption cells 121 form an absorption surface 121a for adsorbing a substrate 100 (not shown in FIG. 15). FIG. 16 shows an enlarged view of the absorption surface 121a and a cross-sectional view of the absorption cell 121. Absorption grooves 126 are formed in the absorption surface 121a. Further, the absorption grooves 126 are connected to air-intake holes 125. The air-intake holes 125 are connected to an internal space 127 formed inside the absorption cell 121. As the air in the internal space 127 is exhausted by a pump or the like, the intake holes 125 and the absorption grooves 126 have a negative pressure. In this way, a substrate 100 is vacuum-adsorbed onto the absorption surface 121a of each absorption cell 121.

As shown in FIG. 17, a valve 129 is preferably provided for each of the plurality of absorption cells 121. For example, the absorption cells 121 are connected to respective exhaust ports 128. The exhaust ports 128 are connected to piping 130 through the valves 129. The piping 130 is common to the plurality of exhaust ports 128. Further, the piping 130 is connected to exhaust means 131 such as a vacuum pump or an ejector. Therefore, the exhaust means 131 can reduce the pressure in the internal space 127 of each absorption cell 121.

The valves 129 are provided for the respective absorption cells 121. The plurality of valves 129 can be opened and closed independently of each other. The substrate 100 is disposed over the absorption surface 121a. By opening all the valves 129, each of the absorption cells 121 vacuum-adsorbs the bottom surface of the substrate 100.

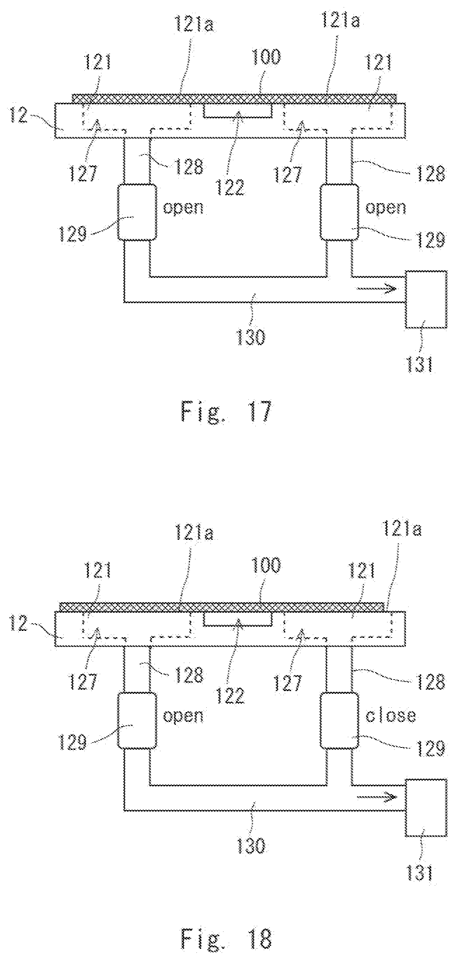

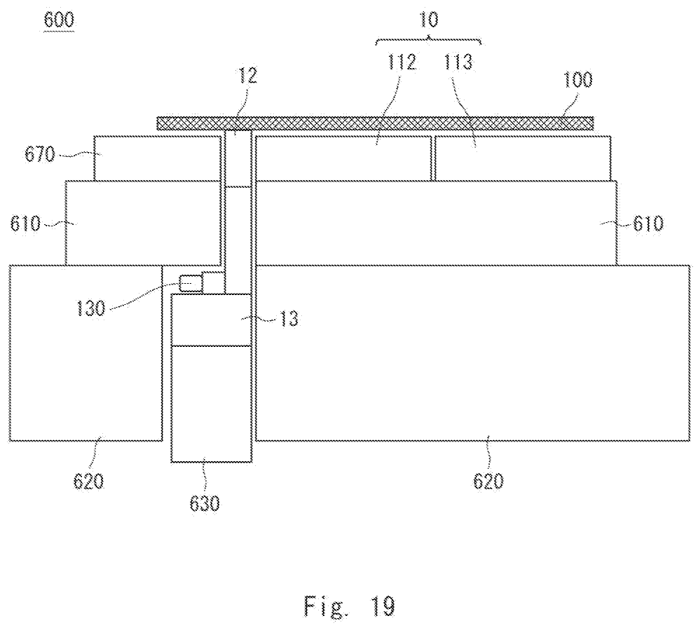

Note that there are cases where, due to an error in the conveyance of the substrate 100, the absorption surfaces 121a of some absorption cells 121 are not closed, i.e., covered, by the substrate 100. As shown in FIG. 18, there are cases where the absorption surfaces 121a of some absorption cells 121 are not completely covered by the substrate 100. In such cases, the valves 129 of the absorption cells 121 whose absorption surfaces 121a are not closed, i.e., covered, are closed. For example, in FIG. 18, the substrate 100 is deviated from the absorption surface 121a of one of two absorption cells 121 located on the right side. Therefore, the valve 129 of the absorption cell 121 located on the right side is closed. In FIG. 18, the substrate 100 is held by only the absorption cell 121 located on the left side. For example, the valve 129 is closed when the sucking flow rate of the gas in the exhaust port 128 increases to a threshold value or higher. In this way, it is possible to appropriately vacuum-adsorb the substrate 100. Therefore, it is possible to perform conveyance of a substrate suitable for a laser irradiation process.

FIG. 19 is a side view schematically showing an example of the overall configuration of the conveyance apparatus 600. The conveyance apparatus 600 includes an area base 610, a pedestal 620, and a conveyance stage 630. Further, the conveyance apparatus 600 also includes a levitation unit 10, a holding mechanism 12, a moving mechanism 13, and an end levitation unit 670 as described above. As shown in FIG. 17 and the like, piping 130 is connected to the holding mechanism 12 by a coupling or the like.

The area base 610 is provided over the pedestal 620. The levitation unit 10 and the end levitation unit 670 are provided over the area base 610. The end levitation unit 670 is one of the end levitation units 671 to 676 shown in FIGS. 6 to 14.

The levitation unit 10 includes a semi-precision levitation unit 112 and a rough levitation unit 113. The accuracy of levitation by the semi-precision levitation unit 112 is lower than that of the precision levitation unit 111. The accuracy of levitation by the rough levitation unit 113 is lower than those of the semi-precision levitation unit 112 and the precision levitation unit 111.

The holding mechanism 12 is disposed between the levitation unit 10 and the end levitation unit 670. The moving mechanism 13 is disposed over the conveyance stage 630. The moving mechanism 13 includes a guide mechanism or the like provided along the moving direction. The moving mechanism 13 moves the holding mechanism 12 as described above. Therefore, the holding mechanism 12 moves along the edge of the levitation unit 10 through the space (gap) between the levitation unit 10 and the end levitation unit 670. By the above-described configuration, it is possible to apply laser light to the moving substrate 100.

### Third Embodiment

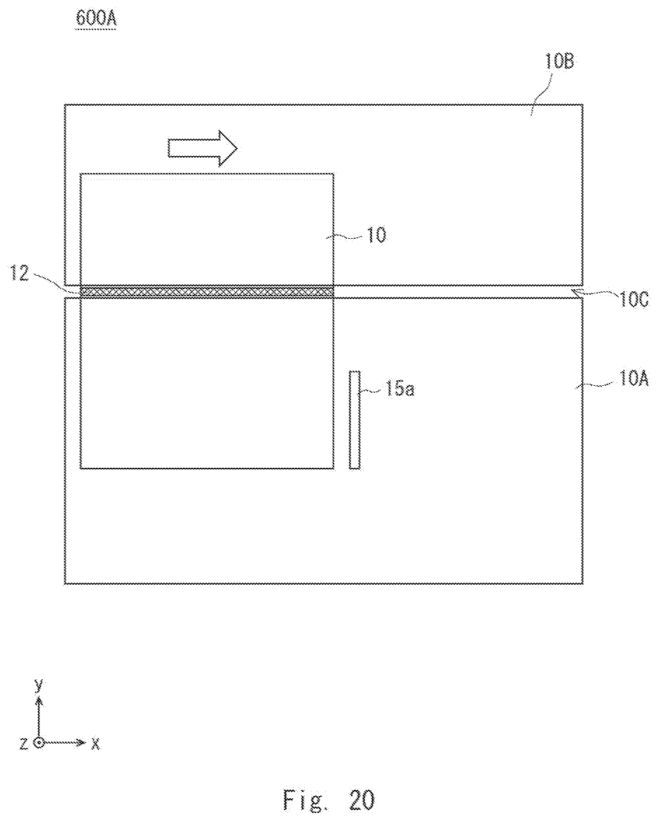

A conveyance apparatus 600A according to a third embodiment will be described with reference to FIG. 20. FIG. 20 is a plan view schematically showing a configuration of the conveyance apparatus 600A. In this embodiment, the levitation unit is divided into two units, i.e., a first levitation unit 10A and a second levitation unit 10B, in order to convey a larger substrate 100. For example, the substrate 100 is a glass substrate of a G10 size (3,130 mm×2,880 mm). Note that the configuration of the conveyance apparatus 600A except for the first and second levitation unit 10A and 10B is similar to those of the first and second embodiments, and therefore the description thereof is omitted as appropriate.

There is a gap 10C between the first and second levitation unit 10A and 10B. That is, the first and second levitation unit 10A and 10B are arranged across the gap 10C. The first and second levitation unit 10A and 10B are disposed below the substrate 100, which is the object to be processed, as in the case of the first and second embodiments. Further, the first and second levitation unit 10A and 10B air-levitate the substrate 100 by ejecting, i.e., blowing, a gas onto the bottom surface of the substrate 100. Laser light is applied while the levitated substrate 100 is being moved. The irradiation area 15a of the laser light has a line-like shape along the y direction. The irradiation area 15a is formed in the first levitation unit 10A.

In FIG. 20, the holding mechanism 12 is moved along the x direction by the moving mechanism 13 (not shown in FIG. 20). In the plan view, the conveyance direction of the substrate 100 is parallel to the x direction. The holding mechanism 12 moves along the gap 10C. The holding mechanism 12 absorbs and holds the central part of the substrate 100, instead of absorbing and holding the end thereof. In the plan view, the first levitation unit 10A is disposed at a part of the substrate 100 extending from the central part of the substrate 100 to one end thereof. In the plan view, the second levitation unit 10B is disposed at another part of the substrate 100 extending from the central part of the substrate 100 to the other end thereof.

In FIG. 20, the first levitation unit 10A is disposed on the −y side of the holding mechanism 12, and the second levitation unit 10B is disposed on the +y side of the holding mechanism 12. Therefore, the first levitation unit 10A air-levitates the part of the substrate 100 extending from the central part of the substrate 100 to the edge thereof on the −y side. The second levitation unit 10B is air-levitated the other part of the substrate 100 extending from the central part of the substrate 100 to the edge thereof on the +y side. As described above, in this embodiment, the first and second levitation unit 10A and 10B, both of which air-levitate the central part of the substrate 100, are provided. The holding mechanism 12 holds the inner part of the substrate 100, instead of holding the end thereof.

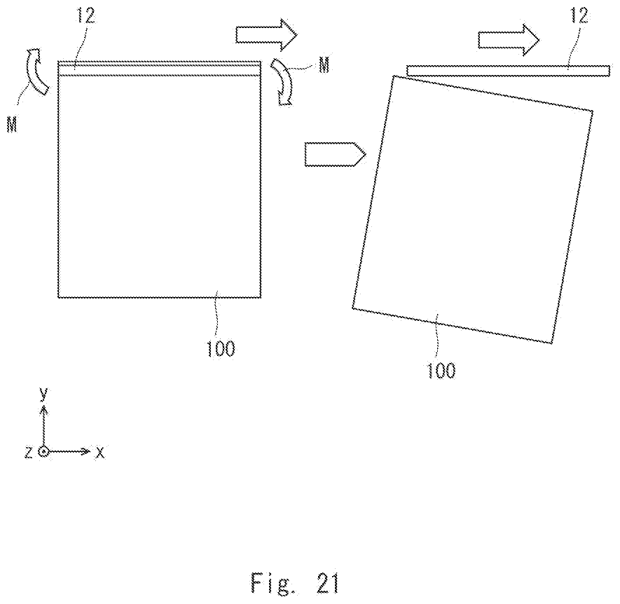

As the holding mechanism 12 holds the central part of the substrate 100, the substrate 100 can be reliably absorbed and held. This feature will be described with reference to FIG. 21. FIG. 21 is a schematic diagram for explaining a case where the end of the substrate 100 is held.

When a rotational force around the z-axis is applied to the substrate 100, a moment of inertia M (hereinafter also referred to as an inertial moment M) acts on the part held by the holding mechanism 12. When the holding mechanism 12 is holding the end of the substrate 100, the inertial moment M is larger than when the holding mechanism 12 is holding the central part of the substrate 100. The larger the substrate 100 is, the larger the inertial moment M becomes. When the inertial moment M becomes large, there is a risk that the vacuum absorption of the holding mechanism 12 could be detached, i.e., the substrate 100 is detached from the holding mechanism 12.

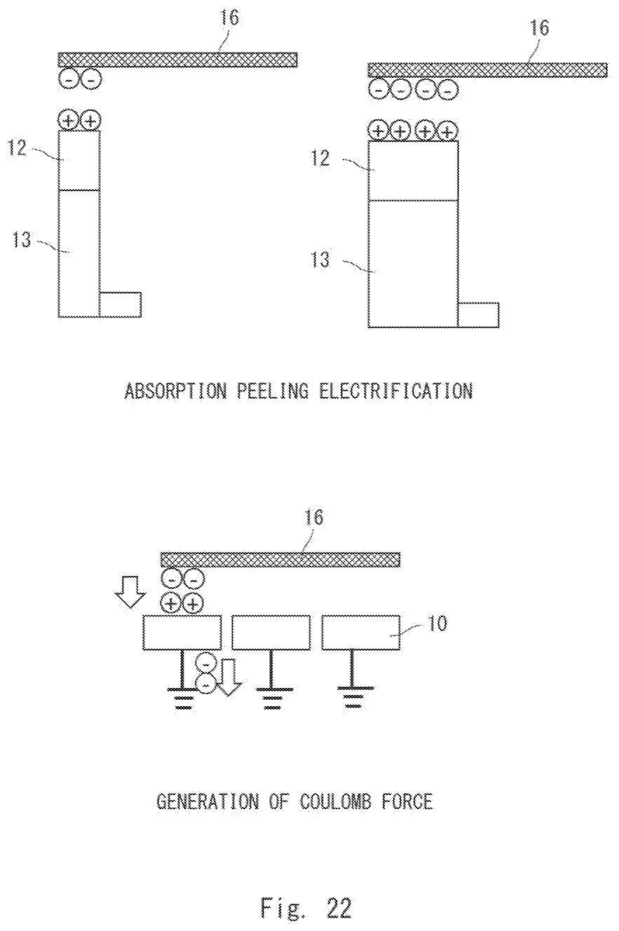

It is possible to increase the absorption force by increasing the width of the holding mechanism 12 in the y direction. However, when the width of the holding mechanism 12 is increased, the contact area between the substrate 100 and the holding mechanism 12 increases. Therefore, as shown in FIG. 22, electrification, i.e., electrical charging, of the substrate 100 becomes problematic. For example, the substrate 100 is electrically charged by the absorption peeling electrification that occurs when the substrate 100 is adsorption-destructed (as shown in the upper part in FIG. 22). The amount of electrical charging increases in proportion to the contact area between the substrate 100 and the holding mechanism 12.

The holding mechanism 12 is formed of a metal material. It is possible to release the electric charge in the holding mechanism 12 by connecting the holding mechanism 12 to the ground. Meanwhile, the substrate 100 is made of an insulator such as glass. Therefore, the electric charge in the electrically charged substrate 100 remains in the substrate 100. A Coulomb force occurs between the substrate 100 and the levitation unit 10, causing the substrate 100 to be attracted toward the levitation unit 10 (as show in the lower part in FIG. 22). In this case, there is a risk that the substrate 100 could come into contact with the levitation unit 10, so that both of them could be damaged.

Therefore, in this embodiment, the holding mechanism 12 holds the central part of the substrate 100, instead of holding the end thereof. By doing so, it is possible to reduce the inertial moment that occurs in the part held by the holding mechanism 12, and thereby reduce the planar size of the holding mechanism 12. That is, even when the planar size of the holding mechanism 12 is reduced, it is possible to prevent the absorption/holding of the substrate 100 from being detached (i.e., prevent the substrate 100 being detached from the holding mechanism 12).

The holding mechanism 12 holds the central part of the substrate 100, instead of holding the end thereof. That is, in the plan view, the second levitation unit 10B is disposed over a part of the substrate 100 extending from the edge of the substrate 100 to the central part thereof. The central part of the substrate 100 can be defined as, for example, the place of the substrate 100 that bends and comes into contact with the second levitation unit 10B in a state in which no gas is ejected from the second levitation unit 10B. That is, if the ejection of the gas from the second levitation unit 10B is stopped while the holding mechanism 12 is holding the central part of the substrate 100 and conveying the substrate 100, the substrate 100 will come into contact with the second levitation unit 10B. Further, the end of the substrate 100 can be defined, for example, as the place of the substrate 100 that does not come into contact with the second levitation unit 10B even when the substrate 100 bends in a state in which no gas is ejected from the second levitation unit 10B. Even if the ejection of the gas from the second levitation unit 10B is stopped while the holding mechanism 12 is holding the end of the substrate 100 and conveying the substrate 100, the substrate 100 does not come into contact with the second levitation unit 10B.

In the conveyance method according to this embodiment, the substrate 100 is conveyed in order to apply laser light that forms a linear irradiation area 15a to the substrate 100. A part of the substrate 100 extending from the central part of the substrate 100 to a one end thereof in the plan view is levitated by using the first substrate levitation unit 10A disposed below the substrate 100, another part of the substrate 100 extending from the central part of the substrate 100 to the other end thereof in the plan view is levitated by using the second substrate levitation unit 10B disposed below the substrate 100. The substrate 100 is adsorbed and held by using the holding mechanism 12 disposed below the central part of the substrate 100. In order to move the substrate 100 with respect to the irradiation place of the laser light 15, the holding mechanism 12 is moved along the gap 10C between the first and second levitation unit 10A and 10B.

### (Example of Irradiation Process)

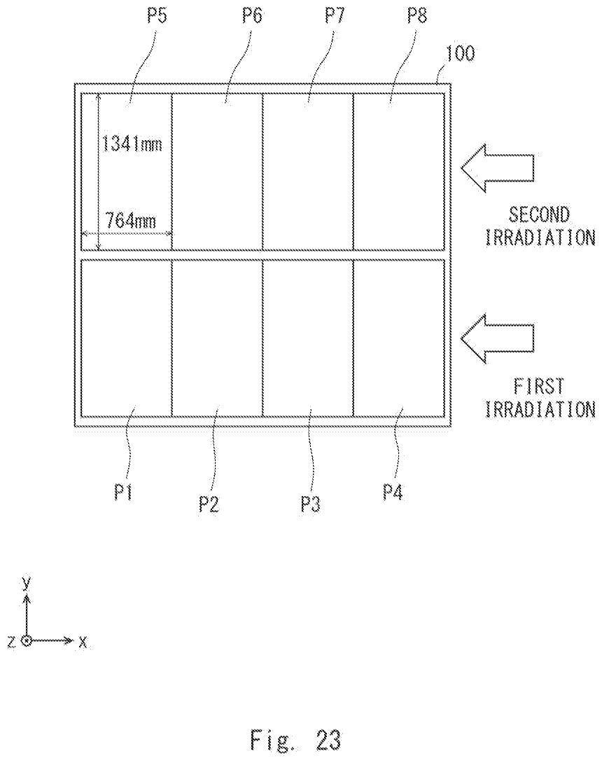

Examples of the irradiation process according to this embodiment will be described hereinafter with reference to FIGS. 23 to 25. Each of FIGS. 23 to 25 schematically shows an irradiation places of laser light in a substrate 100. In each of FIGS. 23 to 25, the substrate 100 is a mother glass substrate for forming a plurality of display panels. The substrate size is, for example, 3,130 mm x 2,880 mm.

### Example 1

An Example 1 shown in FIG. 23 is an example in which eight display panels P1 to P8 are manufactured from one substrate 100. The length of the substrate in the x direction is 3,130 mm, and the length of the substrate in the y direction is 2,880 mm. The panel size of each display panel is 764 mm×1,341 mm. In this case, the length of the irradiation area 15a in the y direction is 1,341 mm or larger. By applying laser light while conveying the substrate 100 in the x direction, substantially a half of the substrate 100 is irradiated with the laser light. In the area irradiated with the laser light, an amorphous silicon film is crystallized and a polysilicon film is formed. Further, by performing the irradiation process twice, the polysilicon film is formed over substantially the entire surface of the substrate 100.

In the first irradiation process, substantially a half of the substrate 100 is irradiated with the laser light. That is, in the first irradiation process, a rectangular area corresponding to a half of the substrate 100 on a one end side thereof is irradiated with laser light. The area that will become the display panels P1 to P4 is irradiated with laser light. In the first irradiation process, the substrate 100 is conveyed in the x direction in a state in which the holding mechanism 12 (not shown in FIG. 23) holds an area that will become at least one of the display panels P5 to P8.

After the first irradiation process, the substrate 100 is rotated around the z-axis by 180°. In the second irradiation process, the remaining half of the substrate 100 is irradiated with the laser light. That is, in the second irradiation process, a rectangular area corresponding to a half of the substrate 100 on the other end side thereof is irradiated with laser light. The area that will become the display panels P5 to P8 is irradiated with laser light. In the second irradiation process, the substrate 100 is conveyed in the x direction in a state in which the holding mechanism 12 holds an area that will become at least one of the display panels P1 to P4. Through the two irradiation processes, substantially the entire surface of the substrate 100 is irradiated with the laser light.

### Example 2

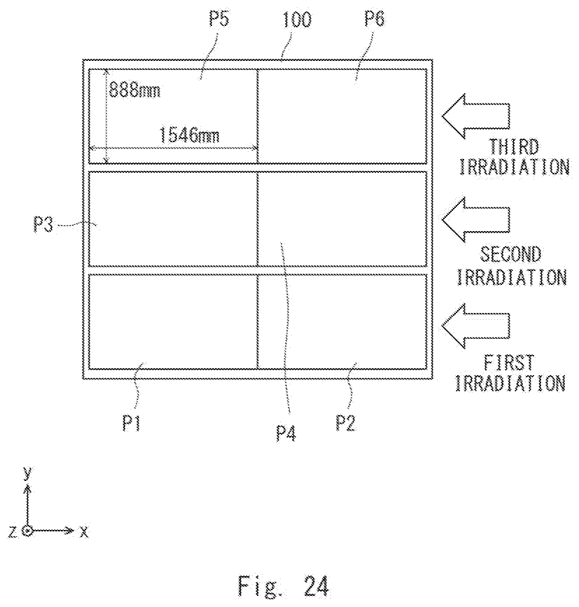

An Example 2 shown in FIG. 24 is an example in which six display panels P1 to P6 are manufactured from one substrate 100. The length of the substrate in the x direction is 3,130 mm, and the length of the substrate in the y direction is 2,880 mm. The panel size of each display panel is 1,546 mm×888 mm. In this case, the size of the irradiation area 15a in the y direction is 888 mm or larger. By applying laser light while conveying the substrate 100 in the x direction, substantially one third of the substrate 100 is irradiated with the laser light. In the area irradiated with the laser light, an amorphous silicon film is crystallized and a polysilicon film is formed. Further, by performing the irradiation process three times, the polysilicon film is formed over substantially the entire surface of the substrate 100.

In the first irradiation process, substantially one third of the substrate 100 is irradiated with the laser light. A rectangular area corresponding to one third of the substrate 100 on a one end side thereof is irradiated with laser light. That is, the area that will become the display panels P1 and P2 is irradiated with laser light. In the first irradiation process, the substrate 100 is conveyed in the x direction in a state in which the holding mechanism 12 (not shown in FIG. 24) holds an area that will become at least one of the display panels P3 to P6.

After the first irradiation process, the substrate 100 is conveyed in the −y direction. In the second irradiation process, substantially one third of the substrate 100 located at the center is irradiated with laser light. In the second irradiation process, a rectangular area corresponding to one third of the substrate 100 including the center thereof is irradiated with laser light. The area that will become the display panels P3 and P4 is irradiated with laser light. In the third irradiation process, the substrate 100 is conveyed in the x direction in a state in which the holding mechanism 12 holds an area that will become at least one of the display panels P5 and P6. Through the two irradiation processes, substantially two third of the substrate 100 is irradiated with laser light.

After the second irradiation process, the substrate 100 is rotated around the z-axis by 180° and conveyed in the y direction. In the third irradiation process, a rectangular area corresponding to one third of the substrate 100 on the other end side thereof is irradiated with laser light. The area that will become the display panels P5 and P6 is irradiated with laser light. In the third irradiation process, the substrate 100 is conveyed in the x direction in a state in which the holding mechanism 12 holds an area that will become at least one of the display panels P1 to P4. Through the three irradiation processes, substantially the entire surface of the substrate 100 is irradiated with the laser light.

Note that the order of the laser-light irradiation processes is not limited to any particular order. For example, the area that will become the display panels P3 and P4 may be irradiated with laser light after irradiating the area that will become the display panels P5 and P6 with laser light. Further, in the first irradiation process, the area that will become the display panels P3 and P4 may be irradiated with laser light.

### Example 3

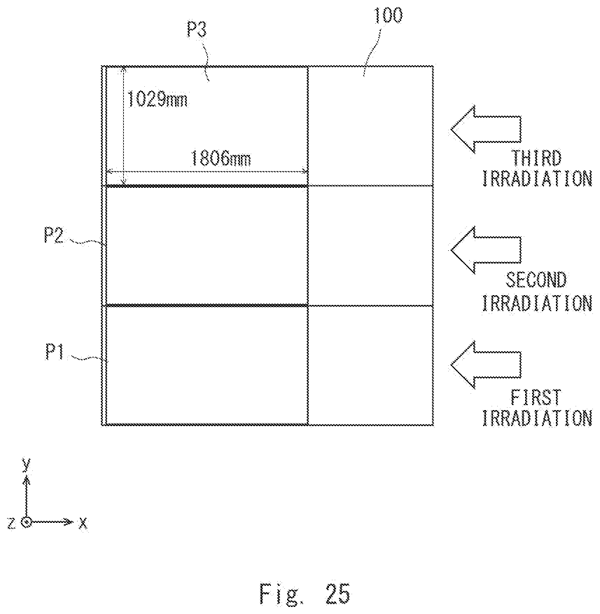

An Example 3 shown in FIG. 25 is an example in which three display panels P1 to P3 are manufactured from one substrate 100. The length of the substrate in the x direction is 2,880 mm, and the length of the substrate in the y direction is 3,130 mm. The panel size of each display panel is 1,806 mm×1029 mm. In this case, the size of the irradiation area 15a in the y direction is 1,029 mm or larger. By applying laser light while conveying the substrate 100 in the x direction, substantially one third of the substrate 100 is irradiated with the laser light. In the area irradiated with the laser light, an amorphous silicon film is crystallized and a polysilicon film is formed. Further, by performing the irradiation process three times, the polysilicon film is formed over substantially the entire surface of the substrate 100.

In the first irradiation process, substantially one third of the substrate 100 is irradiated with the laser light. A rectangular area corresponding to one third of the substrate 100 on a one end side thereof is irradiated with laser light. That is, the area that will become the display panel P1 is irradiated with laser light. In the first irradiation process, the substrate 100 is conveyed in the x direction in a state in which the holding mechanism 12 (not shown in FIG. 25) holds an area that will become at least one of the display panels P1 and P2.

After the first irradiation process, the substrate 100 is conveyed in the −y direction. In the second irradiation process, substantially one third of the substrate 100 located at the center is irradiated with laser light. In the second irradiation process, a rectangular area corresponding to one third of the substrate 100 including the center thereof is irradiated with laser light. The area that will become the display panel P2 is irradiated with laser light. In the third irradiation process, the substrate 100 is conveyed in the x direction in a state in which the holding mechanism 12 holds an area that will become at least one of the display panels P1 and P3. Through the two irradiation processes, substantially two third of the substrate 100 is irradiated with laser light.

After the second irradiation process, the substrate 100 is rotated around the z-axis by 180° and conveyed in the y direction. In the third irradiation process, a rectangular area corresponding to one third of the substrate 100 on the other end side thereof is irradiated with laser light. The area that will become the display panel P3 is irradiated with laser light. In the third irradiation process, the substrate 100 is conveyed in the x direction in a state in which the holding mechanism 12 holds an area that will become at least one of the display panels P1 and P2. Through the three irradiation processes, substantially the entire surface of the substrate 100 is irradiated with the laser light.

Note that the order of the laser-light irradiation processes is not limited to any particular order. For example, the area that will become the display panels P3 and P4 may be irradiated with laser light after irradiating the area that will become the display panels P5 and P6 with laser light. Further, in the first irradiation process, the area that will become the display panels P3 and P4 may be irradiated with laser light.

In the Examples 2 and 3, about one third of the area of the substrate 100 is irradiated with laser light in one irradiation process. Therefore, the holding mechanism 12 holds the substrate 100 at a place about one third of the substrate size away from the edge of the substrate 100. That is, in the y direction, the second levitation unit 10B has a width equivalent to about one third of the substrate size of the substrate 100. Needless to say, the width of the second levitation unit 10B is not limited to one third of the substrate size. The size of the second levitation unit 10B may be determined by determining the number of times of processes according to the substrate size, the number of panels obtained from one substrate, and the size of the irradiation area 15a of the laser light. For example, the size of each of the first and second levitation unit 10A and 10B may be one fourth of the substrate size or larger.

By the configuration according to this embodiment, it is possible appropriately convey a large substrate 100. Even when a rotating force is applied to the substrate 100, it is possible to prevent the absorption/holding of the substrate from being disengaged, i.e., prevent the substrate being disengaged from the holding mechanism due to the inertial moment. Further, it is possible to reliably hold the substrate 100 with a small absorption area, and thereby to prevent the increase in the amount of electrification, i.e., electrical charging. Therefore, it is possible to prevent the substrate 100 from coming into contact with the first levitation unit 10A or the second levitation unit 10B due to a Coulomb force.

Note that the configuration of the third embodiment can be combined with the configuration(s) of the first or/and second embodiment(s) as desired. For example, in the configuration of the third embodiment, the conveyance direction of the substrate 100 may be inclined from the longitudinal direction of the irradiation area 15a.

### (Organic EL Display)

A semiconductor device having the above-described polysilicon film is suitable for a TFT (Thin Film transistor) array substrate for an organic EL (Electro Luminescence) display. That is, the polysilicon film is used as a semiconductor layer including source regions, channel regions, and drain regions of TFTs.

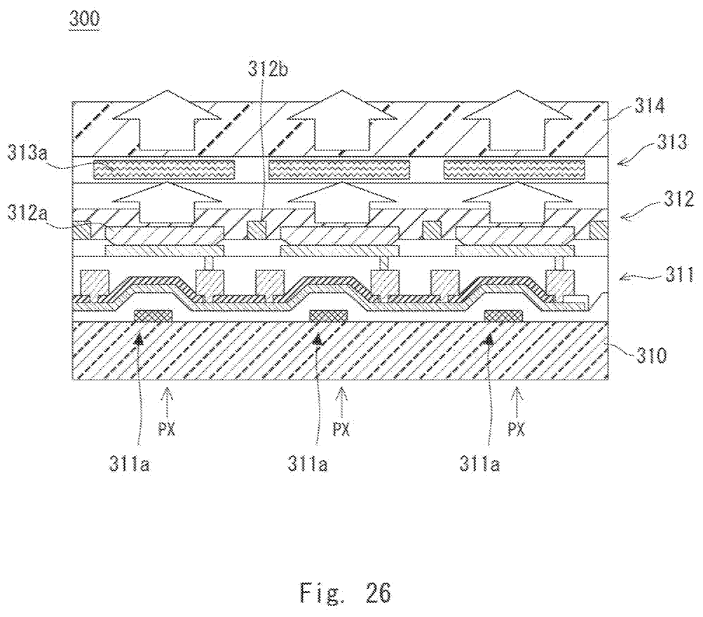

A configuration in which a semiconductor device according to this embodiment is applied to an organic EL display will be described hereinafter. FIG. 26 is a simplified cross-sectional view of pixel circuits of an organic EL display. The organic EL display 300 shown in FIG. 26 is an active matrix-type display device in which a TFT(s) is disposed in each pixel PX.

The organic EL display device 300 includes a substrate 310, a TFT layer 311, an organic layer 312, a color filter layer 313, and a sealing substrate 314. FIG. 26 shows a top-emission-type organic EL display device, in which the side of the sealing substrate 314 is located on the viewing side. Note that the following description is given to show an example of a configuration of an organic EL display device and this embodiment is not limited to the below-described configuration. For example, a semiconductor device according to this embodiment may be used for a bottom-emission-type organic EL display device.

The substrate 310 is a glass substrate or a metal substrate. The TFT layer 311 is provided over the substrate 310. The TFT layer 311 includes TFTs 311a disposed in the respective pixels PX. Further, the TFT layer 311 includes wiring lines (not shown) or the like connected to the TFTs 311a. The TFTs 311a, the wiring, and the like constitute pixel circuits.

The organic layer 312 is provided over the TFT layer 311. The organic layer 312 includes an organic EL light-emitting element 312a disposed in each pixel PX. Further, in the organic layer 312, separation walls 312b for separating organic EL light-emitting elements 312a are provided between pixels PX.

The color filter layer 313 is provided over the organic layer 312. The color filter layer 313 includes color filters 313a for performing color displaying. That is, in each pixel PX, a resin layer colored in R (red), G (green), or B (blue) is provided as the color filter 313a.

The sealing substrate 314 is provided over the color filter layer 313. The sealing substrate 314 is a transparent substrate such as a glass substrate and is provided to prevent deterioration of the organic EL light-emitting elements of the organic layer 312.

Electric currents flowing through the organic EL light-emitting elements 312a of the organic layer 312 are changed by display signals supplied to the pixel circuits. Therefore, it is possible to control an amount of light emitted in each pixel PX by supplying a display signal corresponding to a display image to each pixel PX. As a result, it is possible to display a desired image.

In an active matrix-type display device such as an organic EL display, at least one TFT (e.g., a switching TFT or a driving TFT) is provided in one pixel PX. Further, a semiconductor layer including a source region, a channel region, and a drain region is provided in the TFT in each pixel PX. A polysilicon film according to this embodiment is suitable for a semiconductor layer of TFTs. That is, by using a polysilicon film manufactured by the above-described manufacturing method for a semiconductor layer of a TFT array substrate, it is possible to prevent or reduce in-plane variations of TFT characteristics. Therefore, it is possible to manufacture display devices having excellent display characteristics with high productivity.

### (Method for Manufacturing Semiconductor Device)

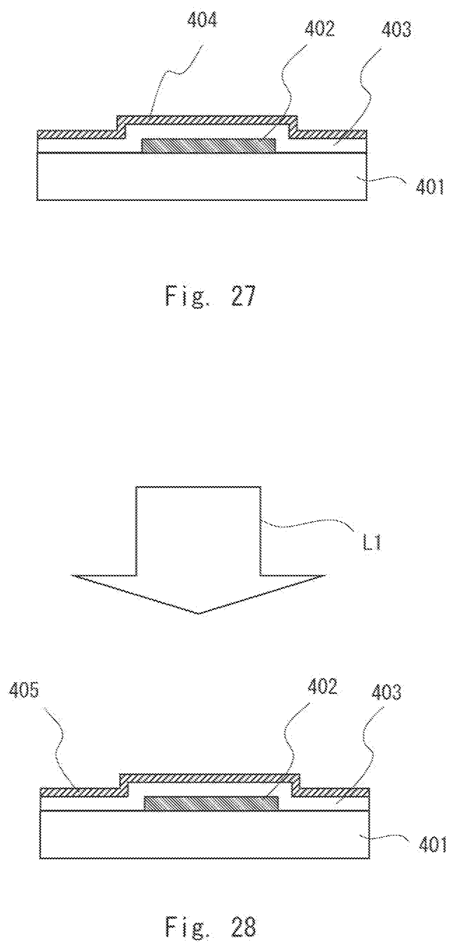

The method for manufacturing a semiconductor device by using a laser irradiation apparatus according to this embodiment is suitable for manufacturing of a TFT array substrate. A method for manufacturing a semiconductor device including a TFT will be described with reference to FIGS. 27 and 28. Each of FIGS. 27 and 28 is a cross-sectional view showing a step in a method for manufacturing a semiconductor device. In the following description, a method for manufacturing a semiconductor device including an inverted staggered-type TFT will be described. Each of FIGS. 27 and 28 shows one of the steps for forming a polysilicon film in a method for manufacturing a semiconductor. Note that other manufacturing steps can be performed by using known techniques, and therefore descriptions thereof are omitted as appropriate.

As shown in FIG. 27, a gate electrode 402 is formed over a glass substrate 401. A gate insulating film 403 is formed over the gate electrode 402. An amorphous silicon film 404 is formed over the gate insulating film 403. The amorphous silicon film 404 is disposed so as to be placed over the gate electrode 402 with the gate insulating film 403 interposed therebetween. For example, the gate insulating film 403 and the amorphous silicon film 404 are successively formed by a CVD (Chemical Vapor Deposition) method.

Then, by irradiating the amorphous silicon film 404 with laser light L1, a polysilicon film 405 is formed as shown in FIG. 28. That is, the amorphous silicon film 404 is crystallized by the laser irradiation apparatus 1 shown in FIG. 1 or the like. As a result, a polysilicon film 405 that is formed as silicon is crystallized is formed over the gate insulating film 403. The polysilicon film 405 corresponds to the above-described polysilicon film 101b.

Further, the above descriptions are given on the assumption that a laser annealing apparatus according to this embodiment is one in which a polysilicon film is formed by applying laser light to an amorphous silicon film. However, the present disclosure may be applied to other cases in which a micro-crystalline film is formed by applying laser light to an amorphous silicon film. Further, the laser light used for the annealing is not limited to Nd:YAG laser. Further, a method according to this embodiment can also be applied to a laser annealing apparatus for crystallizing a thin film other than the silicon film. That is, the method according to this embodiment can be applied to any laser annealing apparatus in which a crystallized film is formed by applying laser light to an amorphous film. According to the laser annealing apparatus in accordance with this embodiment, it is possible to appropriately reform (or modify) a substrate including a crystallized film.

### First Modified Example

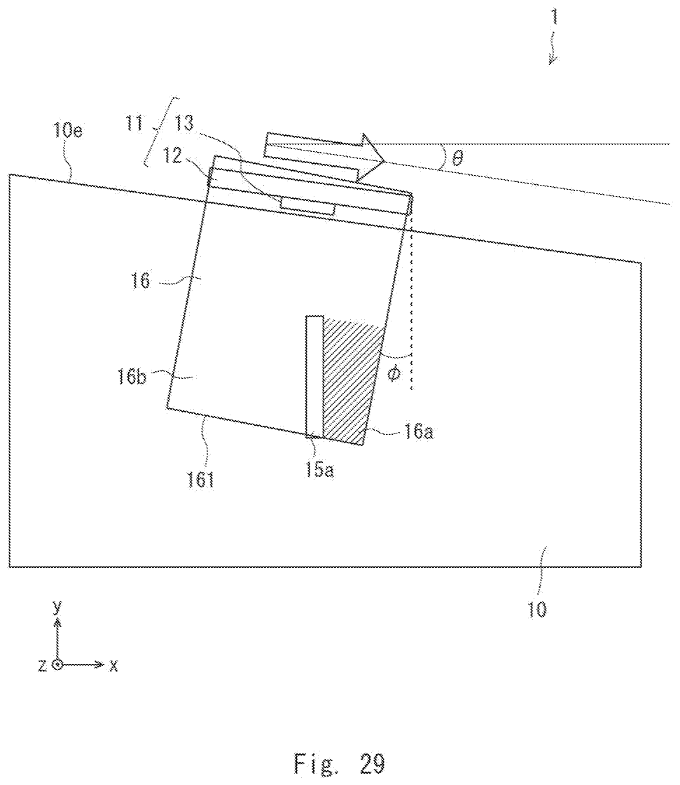

Next, a laser irradiation apparatus using a conveyance apparatus according to a first modified example will be described with reference to FIG. 29. FIG. 29 is a plan view schematically showing a laser irradiation apparatus 1. The fundamental configurations of the conveyance apparatus and the laser irradiation apparatus 1 are similar to those of the first embodiment, and therefore descriptions thereof are omitted as appropriate.

In the modified example, in the plan view, the angle of the object to be processed 16 is different from that in the first embodiment. Specifically, an edge 161 on the −y side of the object to be processed 16 is inclined from the conveyance direction. That is, the conveyance direction and the edge 161 are not parallel to each other. In FIG. 29, the object to be processed 16 is rotated around the Z-axis from the configuration shown in FIG. 1. The angle formed by the edge 161 of the object to be processed 16 to the y direction is represented by φ. Further, the angle between the x direction and the conveyance direction is represented by θ. Although φ is larger than θ in this example, φ may be equal to or smaller than θ.

The angle φ is preferably larger than 0° and not larger than 5°. The angle θ is preferably larger than 0° and not larger than 5°. The angle φ can be adjusted according to the specifications of the laser irradiation process. For example, in the conveyance apparatus 600 shown in FIGS. 6 to 14 described in the second embodiment, the alignment mechanism 69a can change the angle of the substrate 100 to a desired angle. That is, as shown in FIG. 9, the alignment mechanism 69a functions as a driving mechanism that rotates around the Z-axis. The alignment mechanism 69a sets the angle of the edge of the substrate 100 to an angle different from the conveyance direction. By doing so, it is possible to rotate the substrate 100 around the Z-axis before irradiating it with laser light. The conveyance apparatus 600 can convey the substrate 100 while keeping it at the desired angle relative to the line-shaped laser light. After irradiation with the laser light, as shown in FIG. 11, the alignment mechanism 69b rotates the substrate 100 disposed over the levitation unit 10. By doing so, the edge of the substrate 100 becomes parallel to the X direction as shown in FIG. 12.

### Second Modified Example

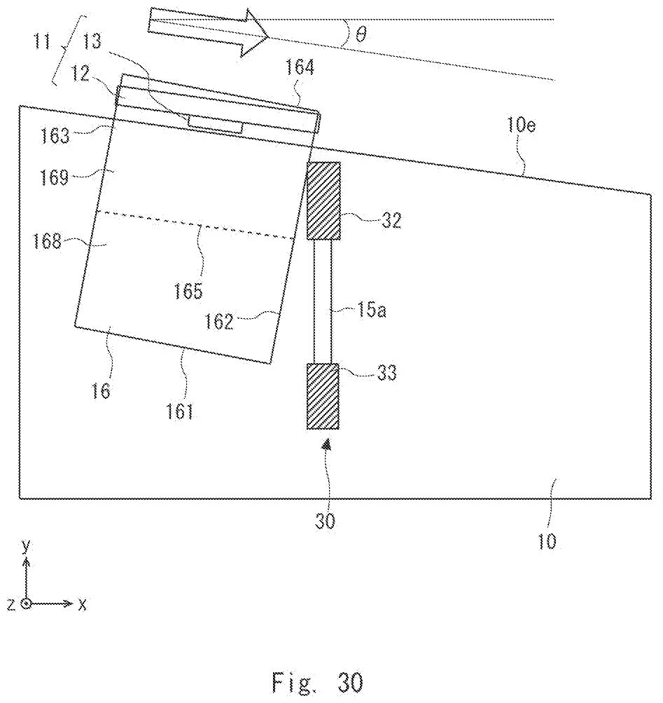

A laser irradiation apparatus according to a second modified example will be described with reference to FIG. 30. A laser irradiation apparatus 1 according to the second modified example includes a slit mechanism 30.

As shown in FIG. 30, in an object to be processed 16 having a rectangular shape, an edge on the +x side is referred to as an edge 162; an edge on the −x side is referred to as an edge 163; and an edge on the +y side is referred to as an edge 164. In the Irradiation Example 1, similarly to FIG. 29, the conveyance direction is inclined from the edges 161 and 164 of the object to be processed 16.

An Irradiation Example in which the entire surface of the object to be processed 16 is irradiated with laser light in two laser irradiation steps will be described. In the object to be processed 16, laser light is applied to areas 168 and 169 one by one. Specifically, the area 168, which is one half of the object to be processed 16, is irradiated with laser light during the first conveyance. The area 168 is an area surrounded by the edges 162, 163 and 161, and a boundary line 165. The boundary line 165 is a straight line parallel to the conveyance direction.

Next, after the object to be processed 16 is rotated 180° around the Z-axis, the second conveyance is performed. By doing so, the area 169, which is the remaining one half of the object to be processed, is irradiated with laser light. That is, a polysilicon film is formed in the area 168 in the first laser irradiation, and a polysilicon film is also formed in the area 169 in the second laser irradiation. The area 169 is an area surrounded by the edges 162, 163 and 164, and the boundary line 165. Note that the areas 168 and 169 may partially overlap each other. In this case, an area on and near the boundary line 165 of the object to be processed 16 is irradiated with laser light twice. Alternatively, a gap may be provided between the area 168, to which laser light is applied in the first irradiation, and the area 169, to which laser light is applied in the second irradiation. In this case, there is an area between the area 168, which is irradiated in the first irradiation, and the area 169, which is irradiated in the second irradiation, in which no laser light is applied. Further, the gap between the areas 168 and 169 may be made as narrow as possible. The boundary line that defines the area 168, which is irradiated in the first irradiation, and the boundary line that defines the area 169, which is irradiated in the second irradiation, do not coincide with each other.

The slit mechanism 30 can adjust the length of the laser light irradiation area 15a in the object to be processed 16. That is, the slit mechanism 30 is a variable-length slit having a variable slit length. In this way, the sizes of the areas 168 and 169, which are irradiated in the first and second laser irradiation steps, respectively, can be freely changed. Specifically, the slit mechanism 30 can change the length of the linear irradiation area 15a in the y direction by adjusting its slit length. For example, the slit mechanism 30 is provided in the optical system of the laser irradiation unit 14 shown in FIG. 2.

The slit mechanism 30 includes a light-shielding part 32 and a light-shielding part 33. Each of the light-shielding parts 33 and 32 has a light-shielding plate or the like that is movably provided along the y direction. The light-shielding parts 33 and 32 can block the ends of the line-shaped laser light. The light-shielding part 33 blocks the end on the −y side of the line beam. That is, the light-shielding part 33 defines the position of the linear irradiation area 15a on the −y side. The light-shielding part 32 blocks the end on the +y side of the line beam. That is, the light-shielding part 32 defines the position of the linear irradiation area 15a on the +y side. Therefore, the position of the light-shielding part 32 defines the position of the boundary line 165.

It is possible to reduce the slit length by moving the light-shielding parts 32 and 33 so that they get close to each other in the y direction. It is possible to increase the slit length by moving the light-shielding parts 32 and 33 so that they recede from each other in the y direction.

Although the light-shielding parts 32 and 33 are provided in the laser irradiation unit 14, in the following description, the positions of the light-shielding parts 32 and 33 are indicated by the positions when they are projected onto the object to be processed 16 by the optical system for simplifying the explanation. For example, in the following description, it is assumed that the position of the light-shielding part 32 corresponds to the end of the irradiation area 15a on the +y side, and the position of the light-shielding part 33 corresponds to the end of irradiation area 15a on the −y side.

The light-shielding parts 33 and 32 move independently of each other. In this way, the slit mechanism 30 can change the length of the line beam and the irradiation end positions in the object to be processed 16. Further, the light-shielding parts 33 and 32 may be moved in an interlocked manner with the conveyance of the object to be processed 16. That is, the positions of the light-shielding parts 32 and 33 may be changed according to the change in the position of the object to be processed 16 during the conveyance. Note that, although the conveyance direction is inclined from the edge 161 of the object to be processed 16 in FIG. 30 as in the case of FIG. 29, the conveyance direction may be parallel to the edge 161 as shown in FIG. 1.

### Irradiation Example 1

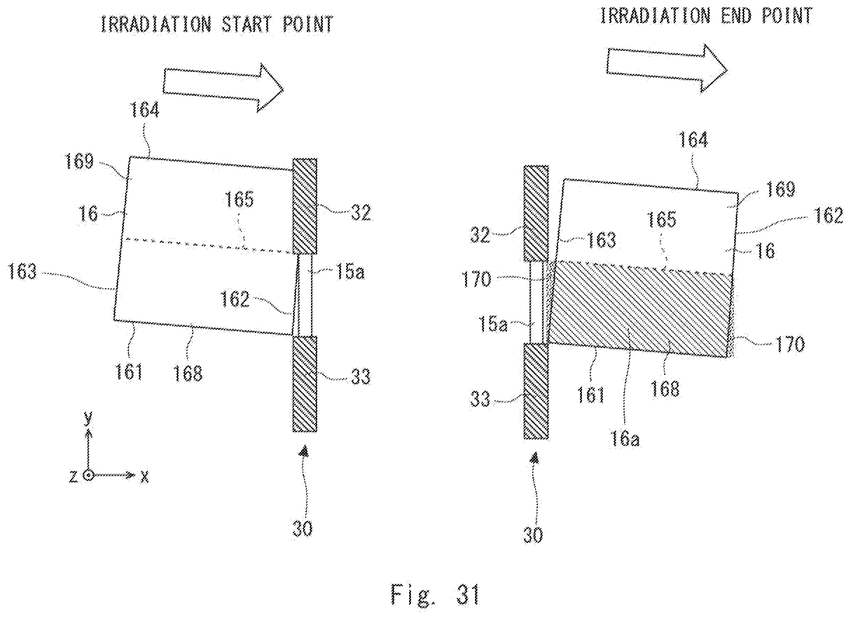

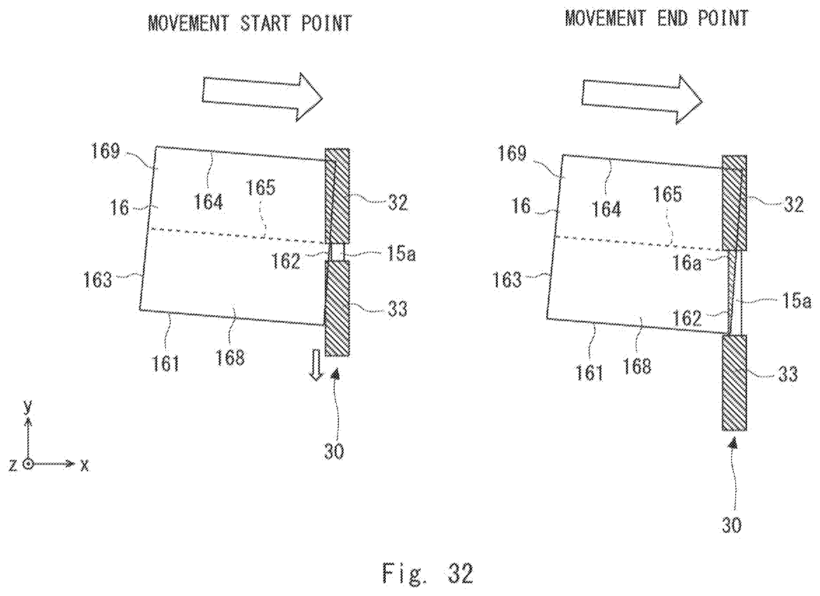

An Irradiation Example 1 will be described with reference to FIG. 31. FIG. 31 shows plan views schematically showing a laser light irradiation area 15a in the object to be processed 16. In the below-shown drawings, the conveyance unit 11 and the levitation unit 10 are omitted as appropriate for simplifying the explanation. In the Irradiation Example 1, similarly to FIG. 1, the edges 161 and 164 of the object to be processed 16 are parallel to the conveyance direction. The boundary line 165 between the areas 169 and 168 is parallel to the conveyance direction and the edge 161.

A configuration at an irradiation start point at which the first irradiation starts is shown on the left side of FIG. 31, and a configuration at an irradiation end point at which the first irradiation ends is shown on the right side of FIG. 31. Note that the irradiation start point means a timing at which the irradiation area 15a overlaps (e.g., coincides with) the edge 162 of the object to be processed 16 by the conveyance. The irradiation end point means a timing at which the irradiation area 15a passes through the edge 163 on the −x side of the object to be processed 16 by the conveyance.

During the first irradiation, the positions of the light-shielding parts 32 and 33 are fixed. The slit length and the irradiation end positions are fixed from the irradiation start point to the irradiation end point. The position of the light-shielding part 33 has been adjusted so that the end position of the irradiation area 15a on the −y side coincides with the edge 161. That is, the light-shielding part 33 forms a line beam so that one end of the irradiation area 15a coincides with the edge 161.

The area 168 is irradiated with laser light by the conveyance of the object to be processed 16. When the irradiation is finished, a polysilicon film 16a is formed in the area 168. When the laser irradiation to the area 168 is finished, the object to be processed 16 is rotated 180° around the Z-axis and it is irradiated with laser light in a similar manner (not shown). As a result, the laser irradiation to the area 169 is completed.

It is possible to reduce the amount of laser light applied to areas outside the substrate, i.e., areas outside the object to be processed 16. For example, in the Irradiation Example 1, the laser light is applied to triangular areas 170 schematically shown in FIG. 31. The areas 170 are areas showing the trajectory of the laser light that is not applied to the object to be processed 16 when the object to be processed 16 is conveyed. In FIG. 31 and the like, for the sake of explanation, the trajectory along which the area that is located outside the object to be processed 16 but is irradiated with the laser light moves as the object to be processed 16 is conveyed is shown as the areas 170. Note that, in practice, the laser light is applied to a fixed position in the levitation unit 10 (see the irradiation area 15a shown in FIG. 1 or 6 or the like). In this case, the laser light irradiation area 15a is formed in the gap between the two precision levitation units 111. By adjusting the position of the light-shielding part 32, it is possible to make the boundary line 165 between the areas 169 and 168 coincide with an area where no device is formed in the object to be processed 16. For example, the boundary line 165 can be formed on a cutting line of the object to be processed 16. In this way, it is possible to prevent variations in irradiation in the device.

### Irradiation Example 2

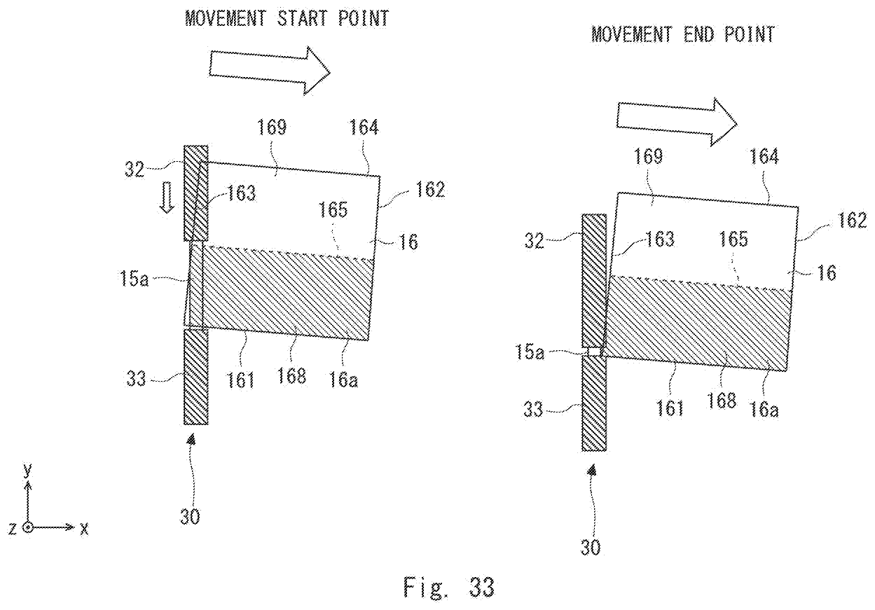

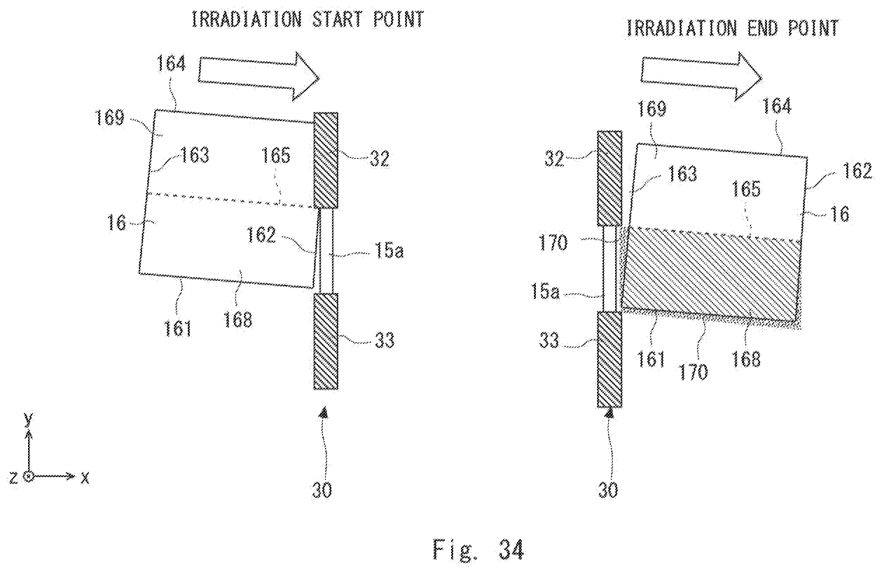

An Irradiation Example 2 will be described with reference to FIGS. 32 and 33. FIGS. 32 and 33 are plan views schematically showing a laser light irradiation area 15a in an object to be processed 16. In the Irradiation Example 2, light-shielding parts 32 and 33 move according to the conveyance of the object to be processed 16. FIG. 32 shows how the edge 162 of the object to be processed 16 is irradiated with laser light. That is, FIG. 32 shows the movement of the light-shielding part 33 at the start of the irradiation to the object to be processed 16. FIG. 33 shows how the edge 163 of the object to be processed 16 is irradiated with laser light. That is, FIG. 33 shows the movement of the light-shielding part 32 at the end of the irradiation to the object to be processed 16. In the Irradiation Example 2, the edge 161 of the object to be processed 16 is parallel to the conveyance direction.

Firstly, the movement of the light-shielding part 33 at the start of the irradiation will be described with reference to FIG. 32. The position of the light-shielding part 33 at a movement start point is shown on the left side of FIG. 32, and the position thereof at a movement end point is shown on the right side of FIG. 32. In FIG. 32, the position of the light-shielding part 32 is fixed.

The light-shielding part 33 moves in the −y direction so as to coincide with the position of the end of the object to be processed 16 on the +x side. During the conveyance of the object to be processed 16, the light-shielding part 33 moves along the edge 162 in the plan view. As a result, a polysilicon film 16a is formed on the −x side of the edge 161 over the entire edge 161.

Specifically, while the irradiation area 15a crosses the edge 162 of the object to be processed 16, the light-shielding part 33 moves in the −y direction. The light-shielding part 33 moves to the edge 161 of the object to be processed 16 so that the laser light is applied to the entire area 168. That is, the light-shielding part 33 gradually moves away from the light-shielding part 32. Therefore, the irradiation area 15a gradually becomes longer according to the movement of the light-shielding part 33. After the light-shielding part 33 has moved to the position at the movement end point in FIG. 32, the position of the light-shielding part 33 is fixed while the object to be processed 16 is being conveyed.

Next, the movement of the light-shielding part 32 at the end of the irradiation will be described with reference to FIG. 33. The position at the movement start point of the light-shielding part 32 is shown on the left side of FIG. 33, and the position at the movement end point of the light-shielding part 32 is shown on the right side of FIG. 33. In FIG. 33, the position of the light-shielding part 33 is fixed.

The light-shielding part 32 moves in the −y direction so as to coincide with the position of the end of the object to be processed 16 on the −x side. During the conveyance of the object to be processed 16, the light-shielding part 33 moves along the edge 163 in the plan view. Specifically, while the irradiation area 15a crosses the edge 163 of the object to be processed 16, the light-shielding part 32 moves in the −y direction. The light-shielding part 32 gradually moves closer to the light-shielding part 33. Therefore, the irradiation area 15a gradually becomes shorter according to the movement of the light-shielding part 32.

In this way, since the area 168 is irradiated with laser light, the polysilicon film 16a is formed over the entire area 168. When the laser irradiation to the area 168 is finished, the object to be processed 16 is rotated 180° around the Z-axis and it is irradiated with laser light in a similar manner. As a result, the laser irradiation to the area 169 is completed. In the Irradiation Example 2, the irradiated area outside the object to be processed 16 can be reduced. Therefore, damage to the levitation unit 10 can be reduced.

### Irradiation Example 3

An Irradiation Example 3 will be described with reference to FIG. 34. FIG. 34 is a plan view schematically showing a laser light irradiation area 15a in an object to be processed 16. A configuration at the irradiation start point is shown on the left side of FIG. 34, and a configuration at the irradiation end point is shown on the right side thereof. The position of the light-shielding part 33 in the Irradiation Example 3 differs from that in the Irradiation Example 1. More specifically, the light-shielding part 33 is disposed so that one end of the irradiation area 15a is positioned on the −y side of the edge 161 of the object to be processed 16. In the Irradiation Example 3, the conveyance direction is parallel to the edge 161. The positions of the light-shielding parts 32 and 33 are fixed.

In the plan view, it is formed so that one end of the irradiation area 15a protrudes from the edge 161 to the −y side thereof. Note that in the Irradiation Example 3, an area 170 which protrudes beyond the object to be processed 16 to the −y side thereof is also irradiated with laser light. It is possible to reliably irradiate the object to be processed 16 including the edge 161 thereof on the −y side with laser light. Therefore, the laser light can be uniformly applied even on and near the edge 161.

### Irradiation Example 4

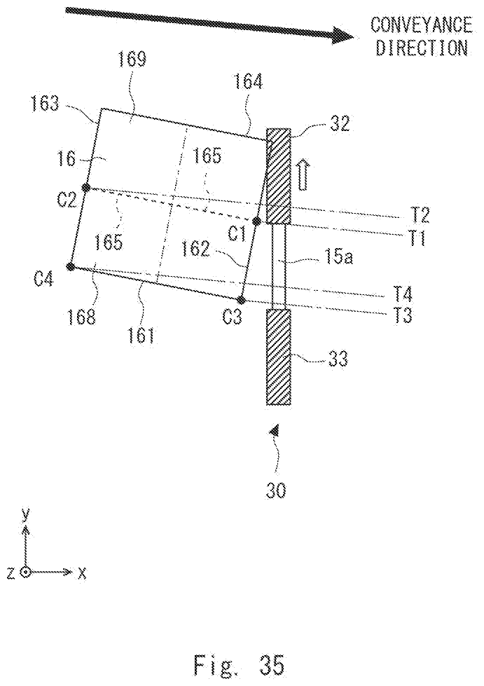

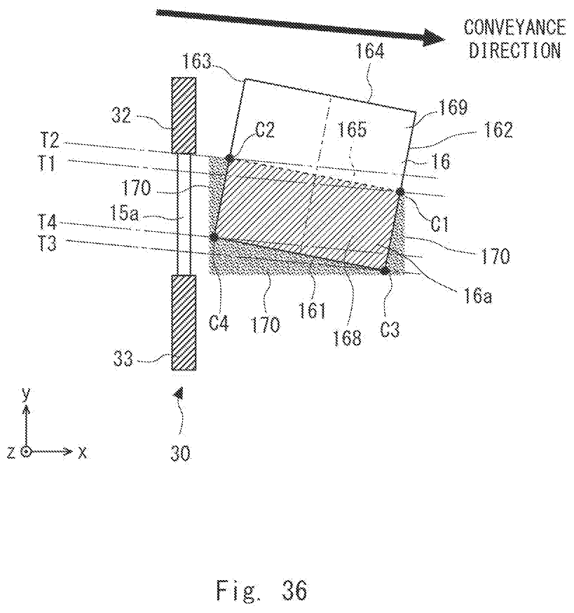

An Irradiation Example 4 will be described with reference to FIGS. 35 and 36. Each of FIGS. 35 and 36 is a plan view schematically showing an object to be processed 16 and a laser light irradiation area 15a. FIG. 35 schematically shows a configuration before the start of the irradiation, and FIG. 36 schematically shows a configuration after the end of the irradiation. In the Irradiation Example 4, the position of the light-shielding part 32 gradually changes during the conveyance of the object to be processed 16. Note that in the Irradiation Example 4, the conveyance direction is inclined from the edge 161.

Firstly, with reference to FIG. 35, points in the object to be processed 16 and their trajectories are defined as follows. As shown in FIG. 35, the intersection between the edge 162 and the boundary line 165 is defined as a point C1. The intersection between the edge 163 and the boundary line 165 is defined as a point C2. The intersection between the edge 162 and the edge 161 is defined as a point C3. The intersection between the edge 163 and the edge 161 is defined as a point C4. The points C3 and C4 correspond to corners of the object to be processed 16 having a rectangular shape.

The trajectories of the points C1 to C4 during the conveyance are represented by trajectories T1 to T4, respectively. For example, when the object to be processed 16 is conveyed in the conveyance direction, the point C1 moves along the trajectory T1. Each of the trajectories T1 to T4 is a straight line parallel to the conveyance direction. In the plan view, from the +y side, they are arranged in the order of trajectories T2, T1, T4 and T3. Further, similarly to the Irradiation Example 3, one end of the irradiation area 15a is positioned on the −y side of the edge 161 of the object to be processed 16. That is, the position of the light-shielding part 33 is adjusted so that the irradiation area 15a protrudes from the edge 161 to the −y side thereof.

In the Irradiation Example 4, when the object to be processed 16 is conveyed along the conveyance direction, it is brought into a state shown in FIG. 36. In FIG. 36, an area 168 on the −y side of the boundary line 165 is irradiated with laser light. While the object to be processed 16 is being conveyed, the light-shielding part 32 moves according to the conveyance. Specifically, when the conveyance speed is fixed, the light-shielding part 32 moves at a constant speed. The light-shielding part 32 gradually moves in the +y direction at the constant moving speed. The light-shielding part 32 moves so that a line connecting the points C1 and C2 coincides with the boundary line 165. Therefore, it is possible to make the boundary line 165 and the edge 161 parallel to each other even when the edge 161 is inclined from the conveyance direction. In other words, the boundary line 165 coincides with a straight line extending in a direction inclined from the conveyance direction.

Further, the irradiation area 15a protrudes beyond the trajectory T3 to −y side thereof. Therefore, the laser light is also applied to the area 170 protruding beyond the object to be processed 16 to −y side thereof. Note that although the light-shielding part 33 is not moved so that the slit length changes according to the conveyance in the Irradiation Example 4, it may be moved so that the slit length changes according to the conveyance. That is, the slit length may be fixed or may be changed.

### Irradiation Example 5

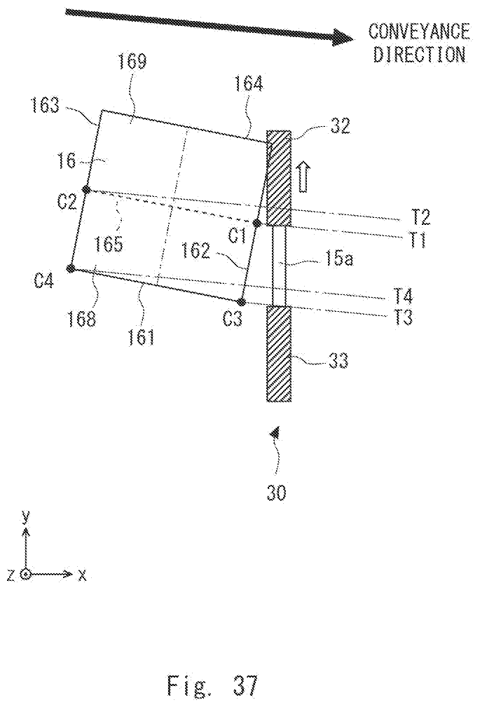

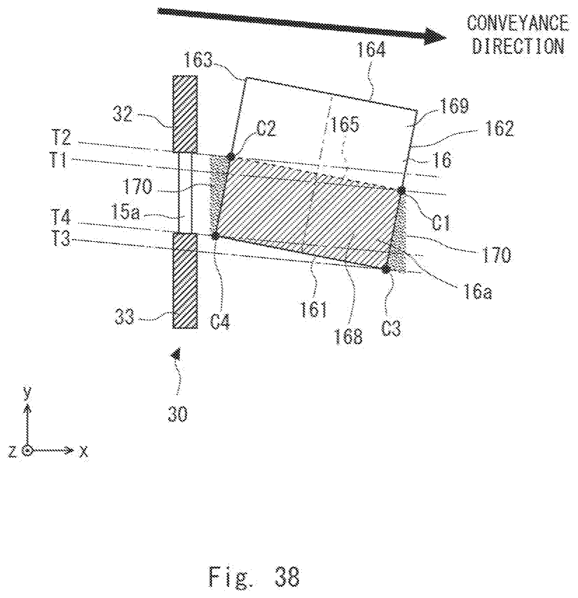

An Irradiation Example 5 will be described with reference to FIGS. 37 and 38. Each of FIGS. 37 and 38 is a plan view schematically showing a configuration in the Irradiation Example 5. FIG. 37 schematically shows a configuration before the start of the irradiation, and FIG. 38 schematically shows a configuration after the end of the irradiation. In the Irradiation Example 5, the light-shielding parts 32 and 33 move according to the conveyance. In the Irradiation Example 5, the light-shielding part 33 is moved in +y direction according to the conveyance.

In the Irradiation Example 5, the position of the light-shielding part 33 changes along the edge 161 according to the conveyance. Further, similarly to the Irradiation Example 4, the position of the light-shielding part 32 changes along the boundary line 165 parallel to the edge 161 according to the conveyance. Therefore, the light-shielding parts 33 and 32 gradually move in the +y direction at the same moving speed. The slit length of the slit mechanism 30 is fixed. The line length of the irradiation area 15a coincides with the distance from the edge 161 to the boundary line 165 in the y direction. In this way, it is possible to prevent the area protruding beyond the object to be processed 16 to the −y side thereof from being irradiated with the laser light. Therefore, a polysilicon film 16a is formed in the area 168.

### Other Embodiment

A holding mechanism capable of performing vacuum absorption with or without a valve may be used as the holding mechanism 12 for holding the object to be processed 16 or the substrate 100. Further, an inert gas such as compressed air or nitrogen can be used as a gas for levitating the object to be processed 16 or the substrate 100.

Although the second embodiment has been described on the assumption that the levitation unit 10 includes the precision levitation unit 111, the semi-precision levitation unit 112, and the rough levitation unit 113, the levitation unit 10 does not have to include all of the precision levitation unit 111, the semi-precision levitation unit 112, and the rough levitation unit 113. That is, the levitation unit 10 may include at least one of the precision levitation unit 111, the semi-precision levitation unit 112, and the rough levitation unit 113. For example, the levitation unit 10 may include only two levitation units, e.g., a precision levitation unit 111 and a rough levitation unit 113. In this case, the rough levitation unit 113 is disposed adjacent to the precision levitation unit 111.

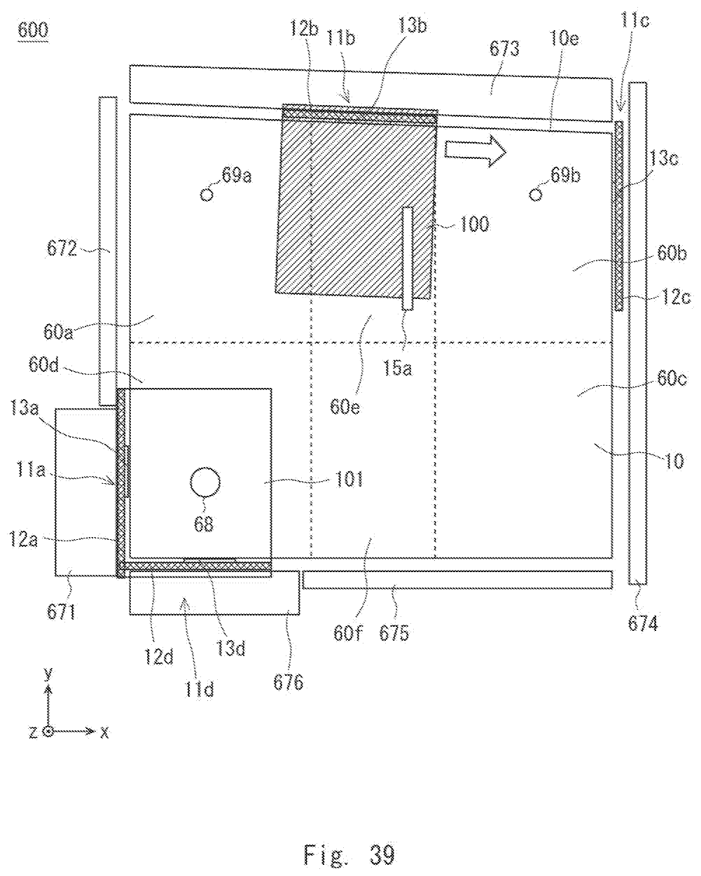

Further, in the conveyance apparatus 600 shown in FIGS. 6 to 14, it is possible to successively irradiate a plurality of substrates with laser light. An example in which the conveyance apparatus 600 levitates and conveys two substrates 100 and 101 simultaneously will be described with reference to FIGS. 39 to 42. Note that descriptions of details of the conveyance apparatus 600 that are substantially the same as those described in the second embodiment will be omitted as appropriate.

As shown in FIG. 39, during the laser irradiation of the first substrate 100, the second substrate 101 is carried into the fourth area 60d of the levitation unit 10. In FIG. 39, laser light is applied to the substrate 100 in the state in which the edge of the substrate 100 is inclined from the Y direction. Then, when the conveyance unit 11b has conveyed the substrate 100 to the second area 60b, the first laser irradiation to the substrate 100 is finished.

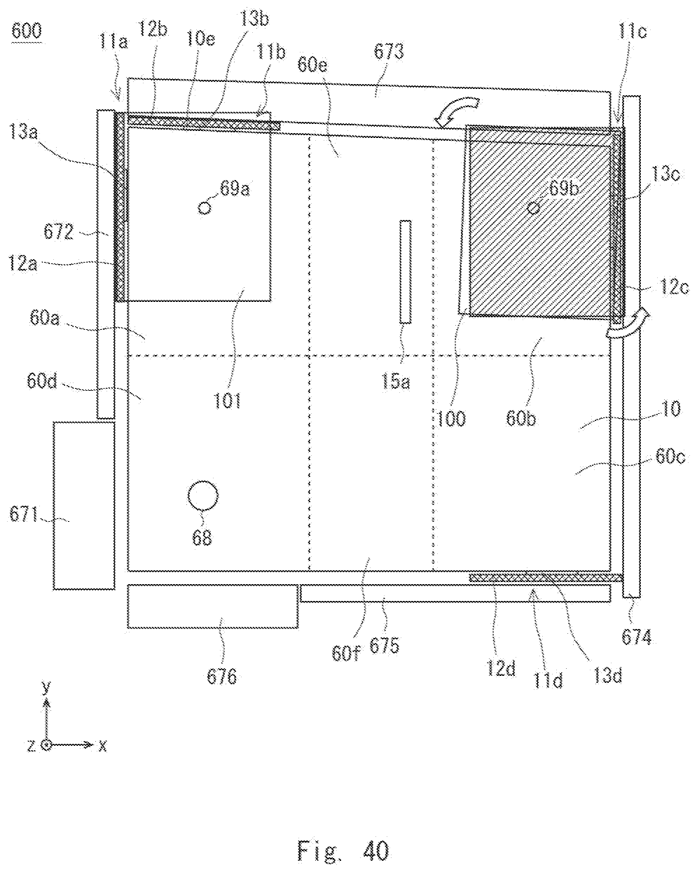

When the laser irradiation to the substrate 100 is finished, the alignment mechanism 69b rotates the substrate 100 as shown in FIG. 40. As a result, the edges of the substrate 100 becomes parallel to the X and Y directions, respectively. At this point, the conveyance unit 11a conveys the substrate 101 in the +Y direction. Therefore, the substrate 101, which had been disposed in the fourth area 60d in FIG. 39, has been moved to the first area 60a in FIG. 40. That is, the conveyance of the substrate 101 by the conveyance unit 11a and the conveyance of the substrate 100 by the conveyance unit 11b are performed simultaneously with each other.

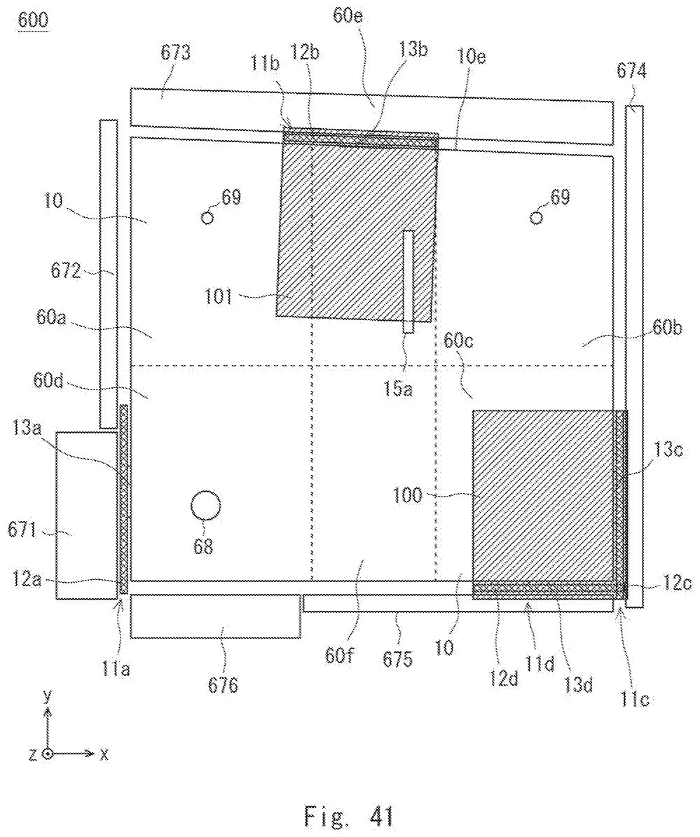

Then, after the alignment mechanism 69a rotates the substrate 101, the conveyance unit 11b conveys the substrate 101. As a result, as shown in FIG. 41, the substrate 101 passes through the irradiation area 15a in the state in which the edge of the substrate 101 is inclined from the Y direction. At this point, the conveyance unit 11c has already conveyed the substrate 100 in the −Y direction. Therefore, the substrate 100, which had been disposed in the second area 60b in FIG. 40, has been moved to the third area 60c in FIG. 41. That is, the conveyance of substrate 101 by the conveyance unit 11b and the conveyance of the substrate 100 by the conveyance unit 11c are performed simultaneously with each other. Then, when the substrate 101 has been conveyed to the second area 60b, the first laser irradiation to the substrate 101 is finished.

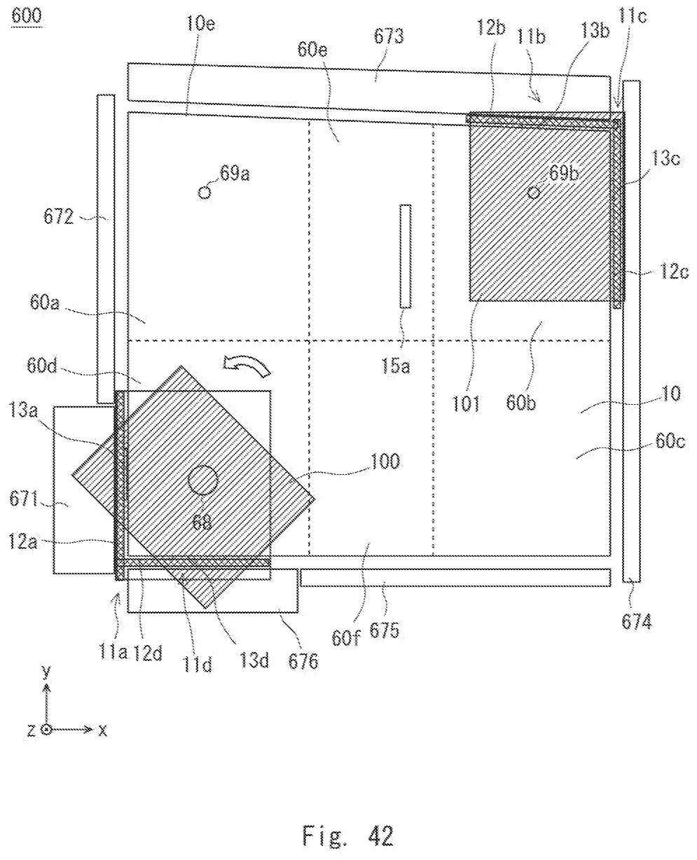

When the laser irradiation to the substrate 101 is finished, the alignment mechanism 69b rotates the substrate 101. As a result, as shown in FIG. 42, the edges of the substrate 101 become parallel to the X and Y directions, respectively. At this point, the conveyance unit 11d has already conveyed the substrate 100 in the −X direction. Therefore, the substrate 100, which had been disposed in the third area 60c in FIG. 41, has been moved to the fourth area 60d in FIG. 42. That is, while the alignment mechanism 69b is rotating the substrate 101, the conveyance unit 11d conveys the substrate 100.

Further, in the fourth area 60d, the rotation mechanism 68 rotates the substrate 100 by 180° as shown in FIG. 42. Then, the above-described processes are repeated for the substrates 101 and 100. That is, the processes shown in FIGS. 39 to 42 are performed after the substrates 101 and 100 are interchanged. Therefore, in the second laser irradiation, the areas that have not been irradiated with laser light in the first laser irradiation are irradiated with laser light. That is, one half of the substrate 100 is irradiated with laser light in the first laser irradiation, and the remaining one half of the substrate 100 is irradiated with laser light in the second laser irradiation.

By doing so, the conveyance apparatus 600 can simultaneously convey a plurality of substrates 100 and 101, which are in a levitated state. The conveyance unit 11a to 11d make the substrates 100 and 101 successively move in a circular manner. As a result, the two substrates 100 and 101 pass through the irradiation area 15a in a successive manner. It is possible to continuously irradiate a plurality of substrates with laser light. Further, the waiting time for carrying in or carrying out substrates to or from the conveyance apparatus 600 can be reduced. As a result, it is possible to reduce the takt time (the cycle time) and thereby improve the productivity. Needless to say, the number of substrates the conveyance apparatus 600 levitates at the same time is not limited to two, but may be three or more.

Note that the present disclosure is not limited to the above-described embodiments, and they can be modified as appropriate without departing from the scope and spirit of the disclosure.

This application is based upon and claims the benefit of priority from Japanese patent application No. 2021-12922, filed on Jan. 29, 2021, the disclosure of which is incorporated herein in its entirety by reference.

### REFERENCE SIGNS LIST

1 LASER IRRADIATION APPARATUS
10 LEVITATION UNIT
11 CONVEYANCE UNIT
12 HOLDING MECHANISM
13 MOVING MECHANISM
14 LASER IRRADIATION UNIT
15 LASER LIGHT
15a IRRADIATION AREA
16 OBJECT TO BE PROCESSED
60a FIRST AREA
60b SECOND AREA
60c THIRD AREA
60d FOURTH AREA
60e PROCESS AREA
60f PASSAGE AREA
670-676 END LEVITATION UNIT
68 ROTATION MECHANISM
69a, 69b ALIGNMENT MECHANISM
100 SUBSTRATE
161 EDGE
162 EDGE
163 EDGE
164 EDGE
165 BOUNDARY LINE
300 ORGANIC EL DISPLAY
310 SUBSTRATE
311 TFT LAYER
311a TFT
312 ORGANIC LAYER
312a ORGANIC EL LIGHT-EMITTING ELEMENT
312b SEPARATION WALL
313 COLOR FILTER LAYER
313a COLOR FILTER (CF)
314 SEALING SUBSTRATE
401 GLASS SUBSTRATE
402 GATE ELECTRODE
403 GATE INSULATOR
404 AMORPHOUS SILICON FILM
405 POLYSILICON FILM
PX PIXEL

1. A conveyance apparatus configured to convey a substrate in order to irradiate the substrate with line-shaped laser light, the conveyance apparatus comprising:
a substrate levitation unit configured to levitate the substrate over its top surface;
a holding mechanism configured to hold the substrate; and
a moving mechanism configured to move the holding mechanism in a direction inclined from a direction perpendicular to a longitudinal direction of the line-shaped laser light in a plan view so as to change an irradiation place of the laser light in the substrate.

2. The conveyance apparatus according to claim 1, wherein
the holding mechanism includes a plurality of absorption cells arranged along a conveyance direction, and
the holding mechanism holds the substrate by having the plurality of absorption cells absorb a bottom surface of the substrate, and
a valve is provided for each of the absorption cells.

3. The conveyance apparatus according to claim 1, wherein
the absorption cell of the holding mechanism is made of a metal material, and
an absorption groove is formed on a top surface of the absorption cells.

4. The conveyance apparatus according to claim 1, wherein an angle formed by the direction perpendicular to the longitudinal direction of the line-shaped laser light and the conveyance direction is larger than 0° and not larger than 5° in a plan view.

5. The conveyance apparatus according to claim 1, wherein
the substrate is rectangular, and
in a plan view, the conveyance direction is inclined from four edges of the substrate.

6. The conveyance apparatus according to claim 1, wherein an angle between the direction perpendicular to the longitudinal direction of the line-shaped laser light and an edge of the substrate is larger than 0° and not larger than 5° in a plan view.

7. The conveyance apparatus according to claim 1, further comprising a rotation mechanism configured to rotate the substrate disposed over the substrate levitation unit.

8. The conveyance apparatus according to claim 1, wherein after the substrate is irradiated with the laser light by conveying the substrate in a state in which an edge of the substrate is inclined from the direction perpendicular to the longitudinal direction of the line-shaped laser light, the edge of the substrate is made parallel to the direction perpendicular to the longitudinal direction of the line-shaped laser light by rotating the substrate disposed over the substrate levitation unit.

9. The conveyance apparatus according to claim 1, further comprising a slit mechanism configured to adjust the irradiation place of the laser light in the longitudinal direction.

10. A conveyance apparatus configured to convey a substrate in order to irradiate the substrate with line-shaped laser light, the conveyance apparatus comprising:
a first substrate levitation unit disposed below the substrate, the first substrate levitation unit being configured to levitate the substrate, and being disposed at a part of the substrate extending from a central part of the substrate to one end thereof in a plan view;
a second substrate levitation unit disposed below the substrate, the second substrate levitation unit being configured to levitate the substrate, and being disposed at another part of the substrate extending from the central part of the substrate to the other end thereof in the plan view;
a holding mechanism disposed below the central part of the substrate, the holding mechanism being configured to hold the substrate by absorbing the substrate; and
a moving mechanism configured to move the holding mechanism along a gap between the first and second substrate levitation units in order to move the substrate with respect to an irradiation place of the laser light.

11. A conveyance method for conveying a substrate in order to irradiate the substrate with line-shaped laser light, the conveyance method comprising the steps of:
(a) levitating, by a levitation unit, the substrate over its top surface;
(b) holding, by a holding mechanism, the substrate; and
(c) moving the holding mechanism in a direction inclined from a direction perpendicular to a longitudinal direction of the line-shaped laser light in a plan view so as to change an irradiation place of the laser light in the substrate.

12. The conveyance method according to claim 11, wherein
the holding mechanism includes a plurality of absorption cells arranged along a conveyance direction, and
the holding mechanism holds the substrate by having the plurality of absorption cells absorb a bottom surface of the substrate, and
a valve is provided for each of the absorption cells.

13. The conveyance method according to claim 11, wherein
the absorption cell of the holding mechanism is made of a metal material, and
an absorption groove is formed on a top surface of the absorption cells.

14. The conveyance method according to claim 11, wherein an angle formed by the direction perpendicular to the longitudinal direction of the line-shaped laser light and the conveyance direction is larger than 0° and not larger than 5° in a plan view.

15. The conveyance method according to claim 11, wherein
the substrate is rectangular, and
in a plan view, the conveyance direction is inclined from four edges of the substrate.

16. The conveyance method according to claim 11, wherein an angle between the direction perpendicular to the longitudinal direction of the line-shaped laser light and an edge of the substrate is larger than 0° and not larger than 5° in a plan view.

17. The conveyance method according to claim 11, wherein the substrate disposed over the substrate levitation unit is rotated before being irradiated with the laser light.

18. The conveyance method according to claim 11, wherein after the substrate is irradiated with the laser light by conveying the substrate in a state in which an edge of the substrate is inclined from the direction perpendicular to the longitudinal direction of the line-shaped laser light, the edge of the substrate is made parallel to the direction perpendicular to the longitudinal direction of the line-shaped laser light by rotating the substrate disposed over the substrate levitation unit.

19. The conveyance method according to claim 11, wherein the irradiation place of the laser light in the longitudinal direction is adjusted by a slit mechanism provided in an optical system for the laser light.

20. A conveyance method for conveying a substrate in order to irradiate the substrate with line-shaped laser light, the conveyance method comprising the steps of:
(A) levitating a part of the substrate extending from a central part of the substrate to one end thereof in a plan view by using a first substrate levitation unit disposed below the substrate, and levitating another part of the substrate extending from the central part of the substrate to the other end thereof in the plan view by using a second substrate levitation unit disposed below the substrate;
(B) holding the substrate by absorbing the substrate by using a holding mechanism disposed below the central part of the substrate; and
(C) moving the holding mechanism along a gap between the first and second substrate levitation units in order to move the substrate with respect to an irradiation place of the laser light.

21. A method for manufacturing a semiconductor device, the method comprising the steps of:
(s1) forming an amorphous film over a substrate; and
(s2) annealing the amorphous film by irradiating the substrate with line-shaped laser light so as to crystallize the amorphous film and thereby form a crystallized film, wherein
the annealing step (s2) includes the steps of:
(sa) levitating, by a levitation unit, the substrate over its top surface;
(sb) holding, by a holding mechanism, the substrate; and
(sc) moving the holding mechanism in a direction inclined from a direction perpendicular to a longitudinal direction of the line-shaped laser light in a plan view so as to change an irradiation place of the laser light in the substrate.

22. The method for manufacturing a semiconductor device according to claim 21, wherein
the holding mechanism includes a plurality of absorption cells arranged along a conveyance direction, and
the holding mechanism holds the substrate by having the plurality of absorption cells absorb a bottom surface of the substrate, and
a valve is provided for each of the absorption cells.

23. The method for manufacturing a semiconductor device according to claim 21, wherein
the absorption cell of the holding mechanism is made of a metal material, and
an absorption groove is formed on a top surface of the absorption cells.

24. The method for manufacturing a semiconductor device according to claim 21, wherein an angle formed by the direction perpendicular to the longitudinal direction of the line-shaped laser light and the conveyance direction is larger than 0° and not larger than 5° in a plan view.

25. The method for manufacturing a semiconductor device according to claim 21, wherein
the substrate is rectangular, and
in a plan view, the conveyance direction is inclined from four edges of the substrate.

26. The method for manufacturing a semiconductor device according to claim 21, wherein an angle between the direction perpendicular to the longitudinal direction of the line-shaped laser light and an edge of the substrate is larger than 0° and not larger than 5° in a plan view.

27. The method for manufacturing a semiconductor device according to claim 21, wherein the substrate disposed over the substrate levitation unit is rotated before being irradiated with the laser light.

28. The method for manufacturing a semiconductor device according to claim 21, wherein after the substrate is irradiated with the laser light by conveying the substrate in a state in which an edge of the substrate is inclined from the direction perpendicular to the longitudinal direction of the line-shaped laser light, the edge of the substrate is made parallel to the direction perpendicular to the longitudinal direction of the line-shaped laser light by rotating the substrate disposed over the substrate levitation unit.

29. The method for manufacturing a semiconductor device according to claim 21, wherein the irradiation place of the laser light in the longitudinal direction is adjusted by a slit mechanism provided in an optical system for the laser light.

30. A method for manufacturing a semiconductor device, the method comprising the steps of:
(S1) forming an amorphous film over a substrate; and
(S2) annealing the amorphous film by irradiating the substrate with line-shaped laser light so as to crystallize the amorphous film and thereby form a crystallized film, wherein
the annealing step (S2) includes the steps of:
(SA) levitating a part of the substrate extending from a central part of the substrate to one end thereof in a plan view by using a first substrate levitation unit, and levitating another part of the substrate extending from the central part of the substrate to the other end thereof in the plan view by using a second substrate levitation unit;
(SB) holding the substrate by absorbing the substrate by using a holding mechanism disposed below the central part of the substrate; and
(SC) moving the holding mechanism along a gap between the first and second substrate levitation units in order to move the substrate with respect to an irradiation place of the laser light.
